(19) United States
(12) Patent Application Publication
(10) Pub. No.: US 2026/0144024 A1
(43) Pub. Date: May 21, 2026

(54) METHODS, DEVICES, AND SYSTEMS FOR ADJUSTING DROP PATTERNS BASED ON OVERBURDEN CHANGES

(71) Applicant: CANON KABUSHIKI KAISHA, Tokyo (JP)

(72) Inventors: Ecron D. Thompson, Round Rock, TX (US); Xing Yee Gan, Portland, OR (US); Craig William Cone, Austin, TX (US)

(21) Appl. No.: 18/953,650

(22) Filed: Nov. 20, 2024

(51) Int. Cl. H01L 21/3105; G03F 7/00

(52) U.S. Cl. CPC H10P 95/06; G03F 7/0002

(57) ABSTRACT

Methods, devices, and systems obtain a first drop pattern, for a wafer, that forms a first planarized film with a first overburden thickness, wherein the first drop pattern has a first drop-pattern radius; obtain a target overburden thickness; and generate a second drop pattern for the wafer based on a second drop-pattern radius, on the target overburden thickness, and on a volume requirement of the wafer.

### BACKGROUND

Technical Field: This application generally concerns generating drop patterns for imprint lithography and inkjet-based adaptive planarization.

Background: Nano-fabrication includes the fabrication of very small structures that have features that are 100 nanometers or smaller. One application of nano-fabrication is the fabrication of integrated circuits. The semiconductor-processing industry continues to strive for larger production yields while increasing the circuits per unit area formed on a substrate. Improvements in nano-fabrication include providing greater process control and increasing throughput while also allowing continued reduction of the minimum feature dimensions of the structures formed.

Some nano-fabrication techniques are commonly referred to as nanoimprint lithography. Nanoimprint lithography is useful in a variety of applications including, for example, fabricating one or more layers of integrated devices. Examples of integrated devices include CMOS logic, microprocessors, NAND Flash memory, NOR Flash memory, DRAM memory, MRAM, 3D cross-point memory, Re-RAM, Fe-RAM, STT-RAM, MEMS, optical components, and the like.

Additionally, planarization techniques are useful in fabricating semiconductor devices. For example, the process for creating a semiconductor device may include repeatedly adding and removing material to and from a substrate. This process can produce a layered substrate with an irregular height variation (i.e., relief pattern), and, as more layers are added, the substrate's height variation can increase. The height variation negatively affects the ability to add further layers to the layered substrate. Moreover, semiconductor substrates (e.g., silicon wafers) themselves are not always perfectly flat and may include an initial surface height variation (i.e., relief pattern). One technique to address height variations is to planarize the substrate between layering procedures. A planarization technique sometimes referred to as inkjet-based adaptive planarization (IAP) involves dispensing a variable drop pattern of polymerizable material between the substrate and a superstrate, where the drop pattern varies depending on the substrate's relief pattern. A superstrate is then brought into contact with the polymerizable material, after which the material is polymerized on the substrate, and the superstrate removed.

Various lithographic patterning techniques benefit from patterning on a planar surface. In ArFi laser-based lithography, planarization improves depth of focus (DOF), critical dimension (CD), and critical dimension uniformity. In extreme ultraviolet lithography (EUV), planarization improves feature placement and DOF. In nanoimprint lithography (NIL), planarization improves feature filling and CD control after pattern transfer.

Also, some nanoimprint lithography techniques form a feature pattern in a formable material (polymerizable) layer and transfer a pattern corresponding to the feature pattern into or onto an underlying substrate. The patterning process uses a template spaced apart from the substrate, and a formable liquid is applied between the template and the substrate. The formable liquid is solidified to form a solid layer that has a pattern conforming to a shape of the surface of the template that is in contact with the formable liquid. After solidification, the template is separated from the solidified layer such that the template and the substrate are spaced apart. The substrate and the solidified layer are then subjected to additional processes, such as etching processes, to transfer a relief image into or onto the substrate that corresponds to the pattern in the solidified layer.

And a substrate with polymerized material can be further subjected to known procedures and processes for device (article) fabrication, including, for example, curing, oxidation, layer formation, deposition, doping, planarization, etching, formable material removal, dicing, bonding, packaging, and the like.

### SUMMARY

Some embodiments of a method comprise obtaining a first drop pattern, for a wafer, that forms a first planarized film with a first overburden thickness, wherein the first drop pattern has a first drop-pattern radius; obtaining a target overburden thickness; and generating a second drop pattern for the wafer based on a second drop-pattern radius, on the target overburden thickness, and on a volume requirement of the wafer.

Some embodiments of a system comprise at least one processor and at least one memory that is in communication with the at least one processor. The at least one memory stores instructions for causing the at least one processor and the at least one memory to obtain a first drop pattern, for a wafer, that forms a first planarized film with a first overburden thickness, wherein the first drop pattern has a first drop-pattern radius; obtain a target overburden thickness; and generate a second drop pattern for the wafer based on a second drop-pattern radius, on the target overburden thickness, and on a volume requirement of the wafer.

Some embodiments of one or more computer-readable storage media store instructions that, when executed by one or more computing devices, cause the one or more computing devices to perform operations that comprise obtaining a first drop pattern, for a wafer, that forms a first planarized film with a first overburden thickness, wherein the first drop pattern has a first drop-pattern radius; obtaining a target overburden thickness; and generating a second drop pattern for the wafer based on a second drop-pattern radius, on the target overburden thickness, and on a volume requirement of the wafer.

### BRIEF DESCRIPTION OF THE DRAWINGS

FIG. 1 illustrates an example embodiment of a shaping system.

FIG. 2A illustrates an example embodiment of a feature pattern on a substrate.

FIG. 2B illustrates an example embodiment of a planarized surface.

FIG. 2C illustrates an example embodiment of a feature pattern on a substrate that has been filled according to its volume requirement.

FIGS. 3A, 3B, and 4 illustrate an example embodiment of a superstrate-chuck assembly.

FIG. 5 illustrates a plan view (a view from along the z axis) of an example embodiment of a substrate, an applique, a feature pattern, and a planarization zone.

FIGS. 6A-B are partial sectional views, taken from line X-X in FIG. 5.

FIGS. 7A-C illustrate a planarization process.

FIG. 8 illustrates example embodiments of a first drop pattern and a second drop pattern.

FIG. 9 illustrates example embodiments of images of top layers on substrates.

FIG. 10 illustrates an example embodiment of an operational flow for generating a drop pattern.

FIG. 11A illustrates an example embodiment of an operational flow for generating a drop pattern.

FIG. 11B illustrates an example embodiment of an operational flow for generating a drop pattern.

FIG. 12A illustrates an example embodiment of an oversized drop pattern.

FIG. 12B illustrates an example embodiment of an oversized drop pattern and a first drop pattern that was generated by cropping the oversized drop pattern according to a specified drop-pattern radius.

FIG. 12C illustrates an example embodiment of an oversized drop pattern and a second drop pattern that was generated by cropping the oversized drop pattern according to a specified drop-pattern radius.

FIG. 13 illustrates an example embodiment of an operational flow for generating a drop pattern.

FIG. 14 illustrates an example embodiment of an operational flow for generating a relationship model.

FIG. 15 is a schematic illustration of an example embodiment of a control device.

### DESCRIPTION

The following paragraphs describe certain explanatory embodiments. Other embodiments may include alternatives, equivalents, and modifications. Additionally, the explanatory embodiments may include several novel features, and a particular feature may not be essential to some embodiments of the devices, systems, and methods that are described herein. Furthermore, some embodiments include features from two or more of the following explanatory embodiments. Thus, features from various embodiments may be combined and substituted as appropriate.

Also, as used herein, the conjunction “or” generally refers to an inclusive “or,” although “or” may refer to an exclusive “or” if expressly indicated or if the context indicates that the “or” must be an exclusive “or.”

Moreover, as used herein, the terms “first,” “second,” “third,” and so on, do not necessarily denote any ordinal, sequential, or priority relation and may be used to more clearly distinguish one member, operation, element, group, collection, set, region, section, etc. from another without expressing any ordinal, sequential, or priority relation. Thus, a first member, operation, element, group, collection, set, region, section, etc. discussed below could be termed a second member, operation, element, group, collection, set, region, section, etc. without departing from the teachings herein.

And in the following description and in the drawings, like reference numbers designate identical or corresponding members throughout the several views.

Furthermore, in this description and the drawings, an alphabetic suffix on a reference number may be used to indicate a specific instance of the feature identified by the reference number. For example, a drop pattern 91 may be identified with the reference number 91 when a particular drop pattern is not being distinguished from other drop patterns, and reference number 91 may be used to collectively refer to the drop patterns. However, 91A may be used to identify a specific drop pattern when the specific drop pattern is being distinguished from the other drop patterns 91.

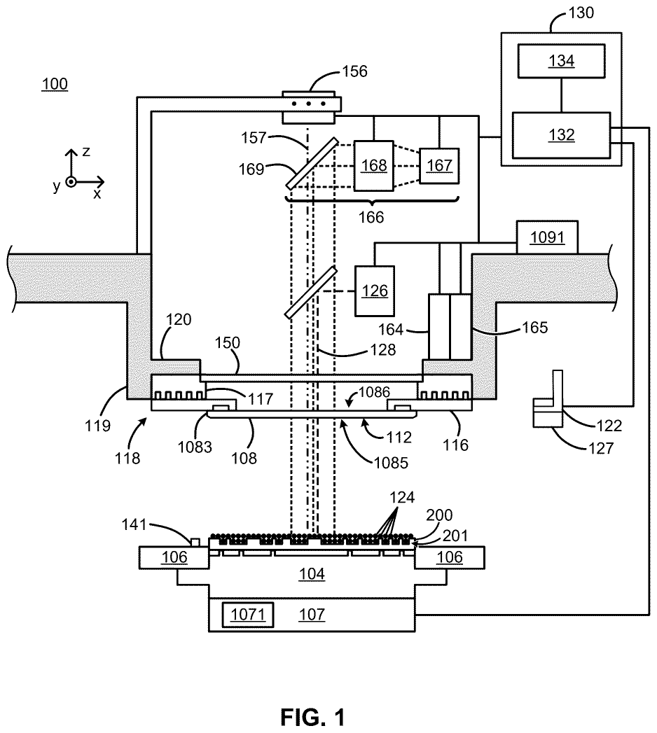

FIG. 1 illustrates an example embodiment of a shaping system 100 (e.g., a nanoimprint lithography system or an inkjet adaptive planarization system). Also, in some embodiments, the shaping system 100 is implemented as a single imprint device. When operating, the shaping system 100 deposits drops of formable material 124 (e.g., resist) on a substrate 200 and uses a superstrate 108 to, for example, planarize the formable material 124 or form a pattern in the formable material 124. The formable material 124 may also be referred to as planarization material.

The substrate 200 may include a feature pattern 201 (a topography) on a surface that is proximal to the superstrate 108. For example, the feature pattern 201 may be a relief pattern. The feature pattern 201 may be composed of doped regions, etched regions, or other modifications. And the feature pattern 201 may also be composed of cured formable material (e.g., resist, planarization material), films of insulating material, or metal. For example, the feature pattern 201 may be composed of etchings in one or more underlying layers. And in some embodiments, the substrate 200 is a wafer.

In the embodiment of the shaping system 100 in FIG. 1, the perimeter of the substrate 200 is surrounded by an applique 106. The applique 106 may be configured to stabilize the local gas environment beneath the superstrate 108 or to help protect the substrate 200 and the formable material 124 from particles, for example when the superstrate 108 is separated from the formable material 124 and the substrate 200. Furthermore, a back surface of the applique 106 may be below (as shown in FIG. 1) or coplanar with the substrate surface.

The substrate 200 is coupled to a substrate chuck 104, which may also support the applique 106. Examples of substrate chucks 104 include the following: vacuum chucks, pin-type chucks, groove-type chucks, electrostatic chucks, and electromagnetic chucks. In some embodiments, such as the embodiment shown in FIG. 1, the applique 106 is mounted on the substrate chuck 104 without any part of the applique being sandwiched between the substrate chuck 104 and the substrate 200. The substrate chuck 104 is supported by the substrate-positioning stage 107.

The substrate-positioning stage 107 may provide translational or rotational motion along one or more of the x-, y-, and z-axes, and the rotational motion may be defined by the θ, ψ, and φ angles. The substrate-positioning stage 107, the substrate 200, and the substrate chuck 104 may also be positioned on a base (not shown). Additionally, the substrate-positioning stage 107 may be a part of a positioning system or a positioning subsystem. One or more actuators 1071 (e.g., voice coil motors, piezoelectric motors, linear motors, nut and screw motors, step motors) supply the forces that move the substrate-positioning stage 107.

The shaping system 100 also includes at least one sensor 141, which is mounted on the applique 106 in this embodiment (although the sensor 141 may be mounted on the substrate chuck 104 in some embodiments). For example, the sensor 141 may be a strain sensor, a spectral-interference displacement sensor (e.g., a spectral-interference laser displacement meter, such as a micro-head spectral-interference laser displacement meter), a capacitance sensor, an air-gauge sensor, an optical-phase sensor, a polarization sensor, or the like. Also, the sensor 141 may include a light emitter that emits light, as well as a corresponding light sensor that measures an intensity of the light. In some embodiments, the sensor 141 generates signals that can be used to detect contaminants (e.g., particles) on the front surface 1085 of the superstrate 108, for example by moving the sensor 141 relative to the superstrate 108 such that the sensor 141 scans the surface of the superstrate 108. Furthermore, the sensor 141 may generate signals that can be used to measure the relative movement of a reflective (or partially reflective) face of the superstrate 108 relative to another component, such as the substrate chuck 104. Also, the sensor 141 may generate signals that can be used to detect an edge of the superstrate 108 or to detect a transition boundary on the superstrate 108. The signals from the sensor 141 may also be used by a control device 130 (described below) to estimate a center of the superstrate 108. And the sensor 141 may generate signals that indicate measurements of the shape of a flexible member 116 or the shape of the superstrate 108. For ease of illustration, the sensor 141 is illustrated as being above the applique 106. But, in some embodiments, a sensing surface of the sensor 141 is coplanar with a gas-controlling surface of the applique 106, below a gas-controlling surface of the applique 106, or below or coplanar with a chucking surface of the substrate chuck 104.

In some embodiments, the superstrate 108 is readily transparent to ultraviolet (UV) light. And examples of materials that may constitute the superstrate 108 include the following: fused-silica, quartz, silicon, organic polymers, siloxane polymers, borosilicate glass, fluorocarbon polymers, metal, and hardened sapphire.

The superstrate 108 has a front surface 1085 that faces the substrate 200, and the front surface 1085 includes a contact surface 112. The superstrate 108 also has a back surface 1086 that faces away from the substrate 200. The contact surface 112 may generally be of the same area or size as, or slightly smaller than, the front surface 1085 of the superstrate 108. The contact surface 112 of the superstrate 108 may be or may include a planar contact surface. In some embodiments (e.g., embodiments that perform Inkjet-based Adaptive Planarization (IAP)), including the embodiment in FIG. 1, the contact surface 112 is featureless. And, in some embodiments, the contact surface 112 includes features that define a pattern that forms the basis of (e.g., an inverse of) a pattern to be formed on the substrate 200. In some embodiments, the contact surface 112 is on a mesa of the superstrate 108. In some embodiments, an area of the contact surface 112 is smaller than an area of the substrate 200, and a step-and-repeat process is used to shape a surface of formable material 124 on the substrate 200.

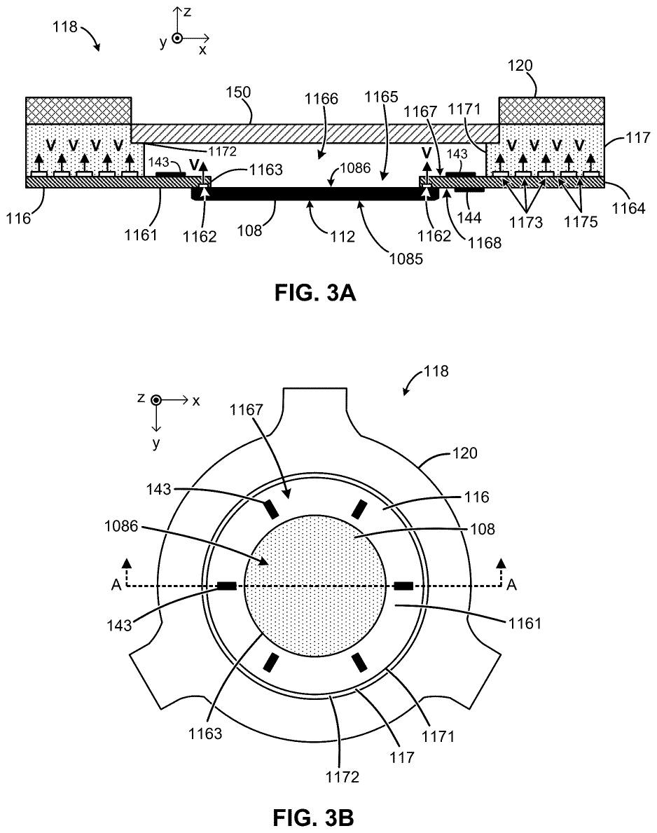

The superstrate 108 is held by a superstrate-chuck assembly 118, which is described below in more detail in the descriptions of FIGS. 3A, 3B, 4, 5A, and 5B. The superstrate-chuck assembly 118 may be coupled to an imprint head 119, which in turn may be moveably coupled to a frame 120 such that the superstrate-chuck assembly 118, the imprint head 119, and the superstrate 108 are moveable in at least the z-axis direction. For example, the imprint head 119 may include one or more actuators 1091 for controlling a relative position of the superstrate-chuck assembly 118. Non-limiting examples of such actuators include the following: voice coil motors, piezoelectric motors, linear motors, nut and screw motors, step motors, etc., that are configured to move the superstrate-chuck assembly 118 and the superstrate 108 in the z-axis direction. In some embodiments, the superstrate-chuck assembly 118, the imprint head 119, and the superstrate 108 are also movable in one or more of the x- and y-axes directions and one or more of the θ, ψ, and φ angles. In some embodiments, the head 119 is not moved in the z-axis direction, and the substrate-positioning stage 107 moves the substrate chuck 104 in the z-axis direction.

The shaping system 100 may include one or more motors or actuators that move the superstrate 108, the superstrate-chuck assembly 118, or the imprint head 119 relative to the substrate chuck 104. For example, the one or more actuators 1091 may rotate the superstrate 108 about an axis in the x-y plane of the superstrate 108. Rotation of the superstrate 108 about an axis in the x-y plane (e.g., a rotation about the x axis, a rotation about the x axis) of the superstrate 108 changes an angle between the x-y plane of the superstrate 108 and the x-y plane of substrate 200, and may be referred herein to as “tilting” the superstrate 108 with respect to the substrate 200, changing a “tilt” or “tilt angle” of the superstrate 108 with respect to the substrate 200, or adjusting the “tilt” or “tilt angle” of the superstrate 108 relative to the substrate 200.

The shaping system 100 also includes a fluid dispenser 122. The fluid dispenser 122 may also be moveably coupled to the frame 120. In some embodiments, the fluid dispenser 122 and the superstrate-chuck assembly 118 share one or more positioning components. And in some embodiments, the fluid dispenser 122 and the superstrate-chuck assembly 118 move independently of each other. Also, in some embodiments, the fluid dispenser 122 and the superstrate-chuck assembly 118 are located in different subsystems of the shaping system 100, and the substrate 200 is moved between the different subsystems.

Different fluid dispensers 122 may use different technologies to dispense the drops of formable material 124. When the formable material is jettable, ink-jet-type fluid dispensers 122 may be used to dispense the drops of formable material 124. For example, thermal ink jetting, microelectromechanical-systems-based (MEMS-based) ink jetting, and piezoelectric ink jetting are technologies for dispensing jettable liquids.

The fluid dispenser 122 may include a fluid-dispense head 127 that includes fluid-dispense ports. The fluid-dispense ports may have a fixed configuration such that the fluid-dispense head 127 and fluid-dispense ports move as a unit and do not move independently of each other. Thus, the fluid-dispense ports may be fixed relative to one another on the fluid-dispense head 127. The number of fluid-dispense ports can vary between embodiments. For example, some embodiments have at least two fluid-dispense ports, at least three fluid-dispense ports, at least four fluid-dispense ports, at least five fluid-dispense ports, at least ten fluid-dispense ports, at least twenty fluid-dispense ports, or over a hundred fluid-dispense ports. In some embodiments, the fluid-dispense ports include a set of at least three fluid-dispense ports that lie along a line. In some embodiments, the fluid-dispense head 127 includes hundreds of fluid-dispense ports that lie along multiple parallel lines.

When operating, the fluid-dispense ports of the fluid dispenser 122 deposit drops of formable material 124 onto the substrate 200 with the volume of deposited material 124 varying over the area of the substrate 200 based at least in part on its feature pattern 201. And the fluid dispenser 122 may deposit the drops of formable material 124 onto the substrate 200 according to a drop pattern, which can define the distribution of the formable material 124 (e.g., drop locations and drop volumes of the drops of the liquid formable material 124) on the substrate 200. The formable material 124 may be, for example, a resist (e.g., photo resist) or another polymerizable material, and the formable material 124 may comprise a mixture that includes a monomer. The drops of formable material 124 may be dispensed upon the substrate 200 before or after a desired field volume (volume requirement) is defined between the contact surface 112 and the substrate 200, depending on the embodiment. The field volume indicates the volume of formable material 124 required to produce all of the desired features on the substrate 200 (e.g., the volume required to cover the feature pattern 201 with, for example, a planar surface). The field volume (volume requirement) includes information about local variations in the volume requirement across the substrate 200. One or both of the substrate 200 and the superstrate 108 have a respective topography (e.g., the feature pattern 201 on the substrate 200), which are described by the volume requirement.

Furthermore, additional formable material 124 may be added to the substrate 200 using various techniques, for example drop dispense, spin-coating, dip coating, chemical vapor deposition (CVD), physical vapor deposition (PVD), thin film deposition, thick film deposition, or the like.

The shaping system 100 also includes an energy source 126 that directs actinic energy (e.g., ultraviolet (UV) radiation) along an exposure path 128. The imprint head 119 and the substrate-positioning stage 107 may be configured to position the superstrate 108 and the substrate 200 on (e.g., in superimposition with) the exposure path 128. The energy source 126 sends the actinic energy along the exposure path 128 after the superstrate 108 has contacted the formable material 124. For illustrative purposes, FIG. 1 shows the exposure path 128 when the superstrate 108 is not in contact with the formable material 124 so that the relative positions of the individual components can be easily identified. However, the exposure path 128 does not substantially change when the superstrate 108 is brought into contact with the formable material 124.

The shaping system 100 also includes at least one imaging device 156 (e.g., camera). FIG. 1 illustrates an optical axis 157 of the imaging device's imaging field. As illustrated in FIG. 1, the shaping system 100 may include one or more optical components (e.g., dichroic mirrors, beam combiners, prisms, lenses, mirrors) that combine the actinic energy with light to be detected by the imaging device 156. Also, the imaging device 156 may be positioned such that an imaging field of the imaging device 156 includes the superstrate 108 and such that the imaging field is in superimposition with at least part of the exposure path 128. Accordingly, the imaging device 156 may be positioned to view the spread of formable material 124 as the superstrate 108 contacts the formable material 124 during the planarization process.

Additionally, the imaging device 156 may include one or more of a CCD sensor, a CMOS sensor, a sensor array, a line camera, and a photodetector that are configured to gather light at a wavelength that shows a contrast between regions underneath the superstrate 108 and in contact with the formable material 124 and regions underneath the superstrate 108 but not in contact with the formable material 124. And the imaging device 156 may be configured to provide images of the spread of formable material 124 underneath the superstrate 108 or of the separation of the superstrate 108 from cured formable material 124. The imaging device 156 may also be configured to measure interference fringes, which change as the formable material 124 spreads between the gap between the contact surface 112 and the substrate surface and a distance between a superstrate front surface 1085 and the substrate topography varies.

In operation, once the drops of formable material 124 have been deposited on the substrate 200, either the imprint head 119, the substrate-positioning stage 107, or both vary a distance between the superstrate 108 and the substrate 200 to define a desired space (a field volume) that is filled by the formable material 124. For example, the imprint head 119 can apply a force to the superstrate 108 that moves the contact surface 112 of the superstrate 108 into contact with the drops of formable material 124 that are on the substrate 200 such that the formable material 124 spreads on the substrate 200. As the superstrate 108 contacts the drops of formable material 124, the drops merge to form a formable-material film 125 that fills the space between the superstrate 108 and the substrate 200. Preferably, the filling process happens in a uniform manner without any air or gas bubbles being trapped between the superstrate 108 and the substrate 200 in order to minimize non-fill defects.

After the desired field volume (volume requirement) is filled with the formable material 124, the energy source 126 produces energy (e.g., actinic radiation) that is directed along the exposure path 128 to the formable material 124 and that causes the formable material 124 to cure (e.g., solidify, cross-link) in conformance to a shape of the substrate's feature pattern 201 and a shape of the contact surface 112. The formable material 124 can be cured while the superstrate 108 is in contact with the formable material 124, thereby forming a planarized surface on the substrate 200 if the superstrate 108 is featureless or a patterned layer if the superstrate 108 has a pattern. Once a cured, planarized layer is formed on the substrate 200, the superstrate 108 can be separated therefrom. And the substrate 200 and the cured, planarized layer may then be subjected to additional known steps and processes for device (article) fabrication, including, for example, patterning, curing, oxidation, layer formation, deposition, doping, planarization, etching, formable material removal, dicing, bonding, and packaging, and the like. The substrate 200 may be processed to produce a plurality of articles (devices).

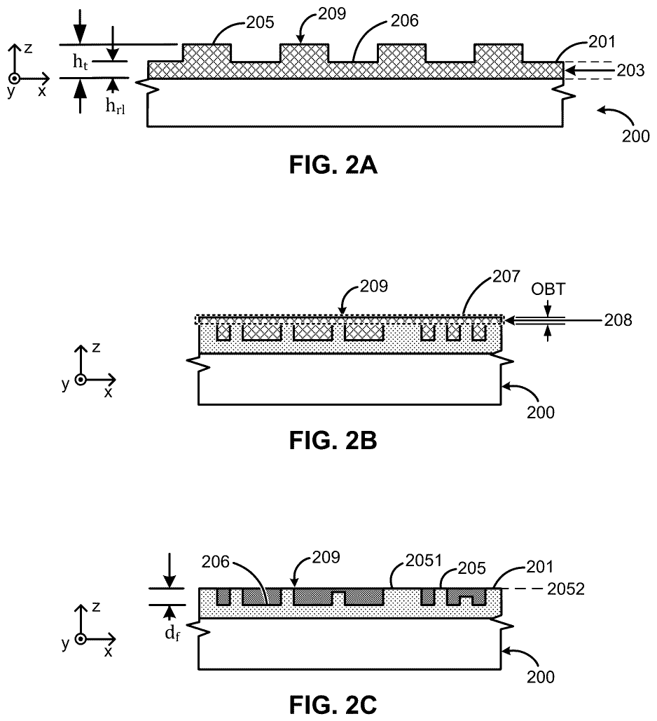

In embodiments of the shaping system 100 that perform IAP, the substrate 200 may have a feature pattern 201 on its surface. For example, FIG. 2A illustrates an example embodiment of a feature pattern 201 on a substrate 200. In FIG. 2A, the substrate 200 has a feature pattern 201 on its back surface 209 (which is the surface that is proximal to the superstrate 108). The feature pattern 201 may include a patterned film that has a residual layer 203 and a plurality of features that are shown as protrusions 205 and recesses 206 that are above the residual layer 203, which may have been made with a patterned superstrate 108. The protrusions 205 have an imprint thickness hₜ, and the residual layer 203 has a residual layer thickness (RLT) hᵣₗ. The feature pattern 201 may also be etched into the substrate 200 or may be the measured topography of an unpatterned wafer.

The drops of formable material 124 may form a patterned top layer that fills the feature pattern 201 on the substrate 200, and the patterned top layer extends above the feature pattern 201. Furthermore, the back surface 209 of the top patterned top layer may be featureless and planar. For example, FIG. 2B illustrates an example embodiment of a planarized surface. FIG. 2B shows a cured, planarized patterned top layer 207 that has been formed on a substrate 200, which included recesses and protrusions prior to the planarization. The cured, planarized patterned top layer 207 fills in the recesses and protrusions that were on the substrate 200. The overburden 208 of the cured, planarized patterned top layer 207 is formed above the feature pattern 201 and has an overburden thickness OBT (e.g., 1-100 nm). The bottom of the overburden 208 lies in a plane that lies on the top of the highest protrusion 205. Thus, the top of the highest protrusion 205 may define the lower border or boundary, in the z-axis direction, of the overburden 208. The field volume (volume requirement) includes (and may be the sum of) the volume requirement of the overburden 208 and the volume requirement of the feature pattern 201. Also, the back surface 209, which faces away from the substrate 200, is featureless and planar.

FIG. 2C illustrates an example embodiment of a feature pattern 201 on a substrate 200 that has been filled according to the volume requirement for only the feature pattern 201 (i.e., the volume requirement of the feature pattern 201). The volume requirement of the feature pattern 201 is the volume of formable material 124 that is required to fill the recesses 206 to the height (level) of the top of the highest protrusion 205. If the top of the highest protrusion 205 is planar, and thus the highest protrusion 205 has a planar top 2051, then the top of the highest protrusion 205 is the plane 2052 of the planar top 2051. In FIG. 2C, multiple protrusions 205 are tied for the highest protrusion 205, and each of these protrusions 205 has a planar top 2051. Also, the fill depth d_{f} (e.g., 5-500 nm) of the feature pattern 201 is the distance between the top of the highest protrusion 205 and the lowest part of the deepest recess 206. And, in some embodiments, the volume requirement of the feature pattern 201 may be described as the total volume of the recesses 206.

The shaping system 100 may be regulated, controlled, or directed by one or more processors 132 in communication with one or more other components or subsystems, such as the substrate-positioning stage 107, the imprint head 119, the fluid dispenser 122, the energy source 126, the imaging device 156, or the sensor 141, and may operate based on instructions in a computer-readable program stored in one or more computer-readable storage media 134. In some embodiments, including the embodiment in FIG. 1, the one or more processors 132 and the one or more computer-readable storage media 134 are included in a control device 130. The control device 130 regulates, controls, or directs the operations of the shaping system 100. Also, the one or more processors 132 and the one or more computer-readable storage media 134 constitute a controller that regulates, controls, or directs the operations of the shaping system 100. Additionally, the control device 130 may constitute a controller, and the shaping system 100 may include a plurality of control devices 130 (at least some of which may constitute respective controllers). Some embodiments of the shaping system include one or more on-tool controllers and several local controllers that receive setpoint controls from the one or more on-tool controllers. The on-tool controllers may receive instructions from tool databases.

Each of the one or more processors 132 may be or may include one or more of the following: a central processing unit (CPU), which may include microprocessors (e.g., a single core microprocessor, a multi-core microprocessor); a graphics processing unit (GPUs); an application-specific integrated circuit (ASIC); a field-programmable-gate array (FPGA); a digital signal processor (DSP); a specially-configured computer; and other electronic circuitry (e.g., other integrated circuits). For example, a processor 132 may be a purpose-built controller or may be a general-purpose controller that has been specially-configured to be an shaping-system controller. The one or more processors 132 may include a plurality of processors that include (i) processors that are included in the control device 130 and (ii) processors that are in communication with the shaping system 100 but not included in the control device 130. And the one or more processors 130 are an example of a processing unit.

Examples of computer-readable storage media 134 include, but are not limited to, a magnetic disk (e.g., a floppy disk, a hard disk), an optical disc (e.g., a CD, a DVD, a Blu-ray), a magneto-optical disk, magnetic tape, semiconductor memory (e.g., a non-volatile memory card, flash memory, a solid-state drive, SRAM, DRAM, EPROM, EEPROM), a networked attached storage (NAS), an intranet-connected computer-readable storage device, and an internet-connected computer-readable storage device.

In the embodiment in FIG. 1, the control device 130 may operate as a drop-pattern-generation device, which generates one or more drop patterns (dispense patterns), and the control device 130 may obtain one or more drop patterns from another device (e.g., a drop-pattern-generation device) that generated (or that store) the one or more drop patterns. For example, the one or more processors 132 may be in communication with a networked computer on which analysis is performed and control files, such as drop patterns, are generated. A drop pattern indicates where the fluid dispenser 122 should deposit drops of liquid formable material 124 onto the substrate 200. A drop pattern may be generated based, at least in part, on one or more of the following: a field volume (volume requirement), a feature pattern 201 of the substrate 200, any pattern that may be on the contact surface 112, a specified overburden thickness (OBT), and a specified wafer-edge exemption zone 213. The exemption zone 213 is the area at the edge of the substrate 200 in which the top layer 207 does not satisfy—or does not need to satisfy—all of the requirements (e.g., quality requirements) of a shaping operation. For example, a requirement for a shaping operation may be a top layer 207 that has a planarity (flatness) that satisfies a planarization target outside the exemption zone 213 (particularly a planarity that satisfies the planarization target in the planarization zone 211), but in the exemption zone 213 the planarity is not required to satisfy the planarization target. Thus, in the exemption zone 213 the planarity can either satisfy or not satisfy the planarization target without affecting the satisfaction of the requirements of the shaping operation. Also, to account for the feature pattern 201 of the substrate 200, the drop density of the drop pattern may vary across the substrate 200. And the drop pattern may have a uniform drop density over regions of the substrate 200 that have a uniform density (e.g., blank areas, or areas where the feature pattern 201 has a uniform feature density).

The shaping system 100 may also include a substrate-heating subsystem 166 (which is an example of a substrate-heating unit). The substrate-heating subsystem 166 deforms a region on the substrate 200 by heating the region on the substrate 200, and the heating may be performed before any formable material 124 has been deposited on the substrate 200; before formable material 124 that has been deposited on the substrate 200 is shaped, planarized, or imprinted; before formable material 124 that has been deposited on the substrate 200 is cured; or while formable material 124 that has been deposited on the substrate 200 is being cured.

The substrate-heating subsystem 166 includes a heating light source 167, which irradiates the substrate 200 with light to heat the substrate 200; an adjusting unit 168, which adjusts the irradiation amount (irradiation amount distribution) of the light; and a reflecting plate 169, which defines an optical path to guide light from the adjusting unit 168 to the substrate 200. In some embodiments, the substrate-heating subsystem 166 is a heat source that may or may not include the heating light source 167 and is incorporated into the substrate chuck 104.

The heating light source 167 emits light that has a wavelength to which the formable material 124, as an ultraviolet curing material, is not photosensitive (not cured), for example, light in a wavelength band of 400 nm to 2,000 nm. For heating efficiency, some embodiments of the heating light source 167 emit light in a wavelength band of 500 nm to 800 nm. However, some embodiments of the heating light source 167 emit light in other wavelength bands. Also, in some embodiments, the heating light source 167 is a laser, such as a high-power laser or an LED array.

The adjusting unit 168 allows only specific light of the emitted light to irradiate the substrate 200 in order to form a predetermined irradiation-amount distribution on the substrate 200. In some embodiments, the adjusting unit 168 includes one or more spatial light modulators (SLMs). An example of an SLM is a mirror array having an array of a plurality of mirrors, each including a drive axis, which may be referred to as digital mirror device (DMD), such as a digital micro-mirror device. A DMD can control (change) an irradiation amount distribution by individually adjusting the plane direction of each mirror.

Furthermore, the imaging device 156 can detect (capture images of) alignment marks and overlay marks. Substrates 200 and superstrates 108 may include corresponding pairs of alignment marks that allow real-time alignment of the superstrates 108 and the substrates 200. After a superstrate 108 is positioned over a substrate 200 (e.g., superimposed over the substrate 200), the control device 130 determines an alignment of the superstrate-alignment marks with respect to the substrate-alignment marks based on the signals (e.g., images) from the imaging device 156. Alignment schemes may include measurement of alignment errors associated with pairs of corresponding alignment marks, followed by compensation of these errors to achieve accurate alignment of the superstrate 108 and a desired imprint location on the substrate 200.

Additionally, substrates 200 and superstrates 108 may include corresponding pairs of overlay marks that allow for assessment of and compensation for overlay errors in imprinted substrates 200. Overlay marks in a superstrate 108 are transferred to the polymeric layer (cured planarized layer 207) during polymerization of the formable material 124, yielding a planarized (or imprinted) substrate 200 with corresponding pairs of overlay marks. The control device 130 may assess overlay errors of corresponding pairs of overlay marks in an imprinted substrate 200 to determine in-plane and out-of-plane contributions to overlay errors. In some embodiments, the superstrate 108 does not have any superstrate-alignment marks, and alignment is based on a superstrate edge 1083 or a contact surface 112 of the superstrate 108. Also, some embodiments include superstrate-alignment marks and also can perform alignment based on a superstrate edge 1083 or a contact surface 112 of the superstrate 108.

And, as noted above, one or both of the substrate-positioning stage 107 and the imprint head 119 can be moved (e.g., translated, rotated) to change the relative positions of the substrate 200 and the superstrate 108. Also, the tilt of the superstrate 108 (or, in some embodiments, the tilt of the substrate 200) can be adjusted. For example, the shaping system 100 may include actuators 1091 (or other devices) that can translate the superstrate 108 about orthogonal axes (the x and y axes in FIG. 1) in the plane of the superstrate 108, rotate the superstrate 108 about an axis orthogonal to the plane of the superstrate 108 (the z axis in FIG. 1), or both. Also for example, some embodiments of the shaping system 100 may translate the superstrate 108 along the z axis and rotate the superstrate 108 about an axis in the plane of the superstrate 108 (the x and y axes in FIG. 1).

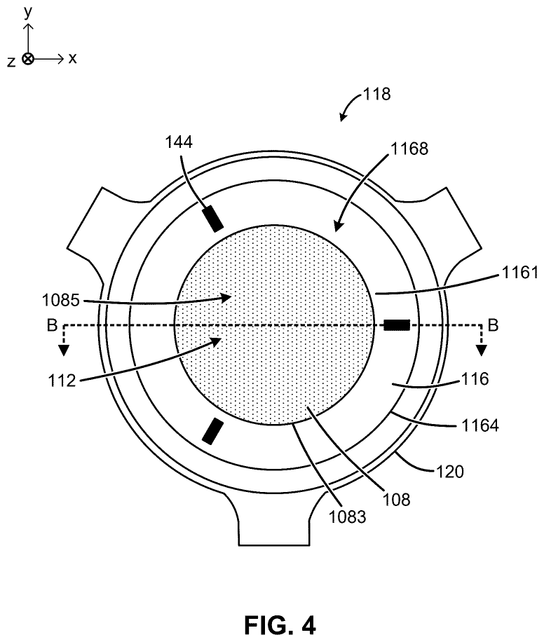

As noted above, the shaping system 100 also includes a superstrate-chuck assembly 118. FIGS. 3A, 3B, and 4 illustrate an example embodiment of a superstrate-chuck assembly 118 (chuck assembly 118). FIG. 3A is a sectional view that is taken along the plane that is indicated by the line AA in FIG. 3B and by the line BB in FIG. 4. FIG. 3B illustrates the example embodiment of the superstrate-chuck assembly 118 in a view that is orthogonal to the view in FIG. 3A, looking in the negative z-axis direction (and FIG. 3B omits the light-transmitting member 150). FIG. 4 illustrates the example embodiment of a superstrate-chuck assembly 118 in a view that is orthogonal to the view in FIG. 3A, looking in the positive z-axis direction.

The chuck assembly 118 includes a flexible member 116 (e.g., a flexible ring portion), which may have an annular shape (e.g., a circular shape) or another shape (e.g., a polygon with a hole) that is formed from the region between two concentric polygons (e.g., squares, rectangles). Thus, the flexible member 116 has both an inner perimeter 1163 and an outer perimeter 1164 and has a central opening 1165. And the shape of the outer perimeter 1164 or the inner perimeter 1163 of the flexible member 116 may be the same as, or similar to, the shape of the superstrate 108. Also, the flexible member 116 may be made of a transparent material that allows UV light to pass through or may not be made of a transparent material that allows UV light to pass through. Thus, the flexible member 116 may or may not be composed of a material that is opaque to UV light. Also, the flexible member 116 may be composed of a plastic (e.g., acrylic), a glass (e.g., fused silica, borosilicate), metal (e.g., aluminum, stainless steel), or a ceramic (e.g., zirconia, sapphire, alumina).

The flexible member 116 includes a flexible portion 1161. The size or shape of the flexible portion 1161 of the flexible member 116 may vary, for example while performing the planarization process or while registering the substrate 200 to the superstrate 108. Any part of the flexible member 116 that is not included in the flexible portion 1161 may be more rigid than the flexible portion 1161 (e.g., may not be flexible). For example, the portions of the flexible member 116 that are closer to the outer perimeter 1164 than to the inner perimeter 1163 may be more rigid than the flexible portion 1161. Accordingly, for example, in some embodiments in which the flexible member 116 has a circular outer perimeter 1164, the flexible portion 1161 has an annular shape, and the other portions of the flexible member 116 (the portions that are not included in the flexible portion) have an annular shape that surrounds the flexible portion 1161.

The flexible member 116 may further include a superstrate-holding cavity 1162 configured to hold a portion of the superstrate 108 to the flexible portion 1161 of the flexible member 116. For example, in some embodiments the superstrate-holding cavity 1162 is an annular cavity that concentrically surrounds the central opening 1165. The superstrate-holding cavity 1162 may be located adjacent to the edge of the inner perimeter 1163 of the member. And the superstrate-holding cavity 1162 may be formed as a recessed portion in the flexible portion 1161. In some embodiments, the inner diameter of the flexible member 116 is smaller or the superstrate-holding cavity 1162 has additional lands.

The chuck assembly 118 may further include a light-transmitting member 150 that is above the central opening 1165 of the flexible member 116. In some embodiments, the light-transmitting member 150 is transparent to UV light with high UV light transmissivity. That is, the material composition of the light-transmitting member 150 may be selected such that UV light used to cure the formable material 124 passes through the light-transmitting member 150. In some embodiments in which the light-transmitting member 150 transmits UV light, the light-transmitting member 150 is composed of a material (e.g., sapphire, fused silica) that transmits greater than 80% of light having a wavelength of 310-700 nm (i.e., UV light and visible light). And in some embodiments, the light-transmitting member 150 is not transparent to UV light. When the light-transmitting member 150 is not transparent to UV light, the light-transmitting member 150 may be composed of a material (e.g., glass, borosilicate) that transmits greater than 80% of light having a wavelength of 400-700 nm (i.e., visible light). That is, in embodiments in which it does not transmit UV light, the light-transmitting member 150 may be able to transmit visible light. Also, the light-transmitting member 150 may transmit light that is emitted by the heating light source 167.

Furthermore, the chuck assembly 118 may include an air cavity 1166. In FIGS. 1, 3A, 5A, and 5B, the surfaces of the air cavity 1166 are formed, at least in part, by an underside surface of the light-transmitting member 150 and a back surface 1167 of the flexible member 116. The surfaces of the air cavity 1166 may be further formed by the inner side wall 1171 of a support ring 117, which is described in more detail below. When the flexible member 116 holds a superstrate 108, the back surface 1086 of the superstrate 108 also forms a surface of the air cavity 1166.

And the chuck assembly 118 may further include a fluid path in communication with the air cavity 1166 for pressurizing the air cavity 1166. As used herein, pressurizing includes both positive pressurizing and negative pressurizing. The fluid path can also be used to open the air cavity 1166 to the surrounding atmosphere. Also, the fluid path is in communication with one or more pressure sources 164 or vacuum sources 165 (e.g., pumps, tanks, fans, fluid lines, vacuum lines) or includes one or more ports that can be coupled to pressure sources 164 or vacuum sources 165. And the fluid path may include components (e.g., one or more valves) that together allow the air cavity 1166 to be selectively positively or negatively pressurized. The one or more pressure sources 164 or vacuum sources 165 constitute a pressure controller, which operates based on signals sent from the one or more processors 132. The pressure controller may include one or more of the following: PID controllers, mass flow controllers, valves, switches, tanks, pumps, etc. that are used to control the dynamic state of fluid in the air cavity 1166. The pressure controller includes electronic components and mechanical components that temporally modulate a pressure of one or more fluids that are supplied to one or more cavities (e.g., the air cavity 1166) of the shaping system 100. The fluid modulated by a pressure supplier (a pressure source 164 or a vacuum source 165) may be supplied from a tank in the shaping system 100 or may be supplied via an external fluid supply.

The superstrate 108 may be held by the flexible portion 1161 by reducing the pressure in the superstrate-holding cavity 1162. One manner of reducing the pressure in the superstrate-holding cavity 1162 is to produce a vacuum in the superstrate-holding cavity 1162. In order to produce a vacuum in the superstrate-holding cavity 1162 of the flexible member 116, the chuck assembly 118 may further include a path (also referred herein as a vacuum path) in communication with the superstrate-holding cavity 1162 and in communication with a vacuum source 165. In a case that there is already a pressure differential within the assembly relative to the atmosphere around the assembly, the vacuum path can be used as a manner of reducing pressure in the superstrate-holding cavity 1162 without being coupled to a vacuum source 165. The vacuum path may include components (e.g., valves) that together allow the superstrate-holding cavity 1162 to generate a vacuum that applies a suction force V to the superstrate 108.

In some embodiments, the superstrate-holding cavity 1162 and the vacuum path are replaced with another mechanism for coupling the flexible member 116 with a superstrate 108. For example, in place of a cavity-vacuum arrangement, an electrode that applies an electrostatic force may be included. Another option is mechanical latching where a mechanical structure on the underside of the flexible member 116 is mateable with the superstrate 108.

The chuck assembly 118 may further include a support ring 117, which may also be referred to as a ring chuck. The support ring 117 does not need to be made of a transparent material that allows for UV light to pass through. Thus, the support ring 117 may be composed of a material that is opaque to UV light. For example, the support ring 117 may be composed of plastic (e.g., acrylic), glass (e.g., fused silica, borosilicate), metal (e.g., aluminum, stainless steel), or ceramic (e.g., zirconia, sapphire, alumina). In some embodiments, the support ring 117 is composed of the same material as the flexible member 116.

The support ring 117 may include a circular (or polygonal shaped) main body defining an open central area, and the shape of the support ring 117 may be the same as, or similar to, the shape of the flexible member 116. The outer circumference of the support ring 117 may be uniform. The inner side wall 1171 of the support ring 117 may include a step that provides a receiving surface 1172 for receiving the light-transmitting member 150. Accordingly, the light-transmitting member 150 may be placed onto the receiving surface 1172 of the step, thereby covering the central area. The light-transmitting member 150 may be secured onto the receiving surface 1172, for example using an adhesive. Thus, when the light-transmitting member 150 is placed or secured onto the receiving surface 1172 and when a superstrate 108 is held by the flexible member 116, the air cavity 1166 is defined by the underside surface of the light-transmitting member 150, the inner side wall 1171 of the support ring 117, the back surface 1167 of the flexible member 116, and the back surface 1086 of the superstrate 108.

The flexible member 116 may be coupled to the underside surface of the support ring 117 using a coupling member (not shown), such as a screw, nut, bolt, adhesive, and the like. The coupling member may be located adjacent to the outer edge of the support ring 117 and adjacent to the outer edge of the flexible member 116. When the coupling member is a screw, the coupling member may pass through the flexible member 116 adjacent to the outer edge and into the support ring 117 adjacent to the outer edge. When the coupling member is an adhesive, the coupling member may be located between the flexible member 116 adjacent to the outer edge and the support ring 117 adjacent to the outer edge. In this manner, a back surface of the flexible member 116 contacts and is fixed to the underside surface of the support ring 117 adjacent to their outer edges.

Additional surface area of the flexible member 116 may be selectively coupled to the support ring 117. The chuck assembly 118 may include additional vacuum paths that allow the flexible member 116 to be selectively secured to the underside surface of the support ring 117. The additional vacuum paths that allow the flexible member 116 to be selectively secured to the underside surface of the support ring 117 may be annular cavities 1173 in the support ring 117 that are open on the underside surface of the support ring 117. When the additional vacuum paths are connected to a vacuum source 165 (e.g., a vacuum pump), and the upper side surface of the flexible member 116 is in contact with the underside surface of the support ring 117, vacuums can be generated in the annular cavities 1173 of the support ring 117 to apply suction forces V to secure the flexible member 116 to the support ring 117.

The number of the annular cavities 1173 may be selected to provide the optimal control over how much surface area of the flexible member 116 is suctioned underneath the support ring 117. For example, in some embodiments, the number of annular cavities 1173 ranges from 1 to 10, from 3 to 7, or from 4 to 6. And the annular cavities 1173 may have varying sizes. The support ring 117 may further include lands 1175 between adjacent annular cavities. The lands 1175 are the portions of the support ring 117 that come into contact with the back surface of the flexible member 116.

The superstrate-chuck assembly 118 may also include one or more strain gauges (strain sensors) that measure the strain of the flexible portion 1161 of the flexible member 116 and output strain information, which includes strain measurements, that indicates the measured strain. The strain gauges may include back-side strain gauges 143 and front-side strain gauges 144. Back-side strain gauges 143 are positioned on the back surface 1167 of the flexible portion 1161 of the flexible member 116. Front-side strain gauges 144 are positioned on a front surface 1168 of the flexible portion 1161 of the flexible member 116. And some embodiments include back-side strain gauges 143 but no front-side strain gauges 144, and some embodiments include front-side strain gauges 144 but no back-side strain gauges 143. Examples of the back-side strain gauges 143 and the front-side strain gauges 144 include the following: linear strain gauges, Rosette strain gauges, and double parallel strain gauges. The strain gauges may be configured in quarter bridge, half-bridge, or full bridge configurations. Also, in some embodiments, the strain of the flexible member 116 may be measured by non-contact techniques, and the strain gauges (back-side strain gauges 143, the front-side strain gauges 144) may include non-contact strain gauges, for example digital-image-correlation (DIC) strain gauges. And the back-side strain gauges 143 and the front-side strain gauges 144 may not all be the same type of strain gauge. The control device 130 can use the strain information to control the shaping system 100.

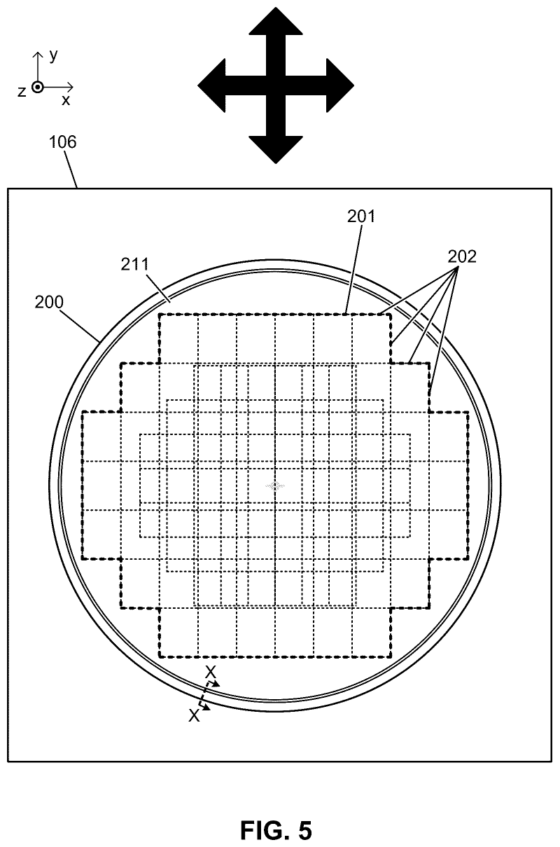

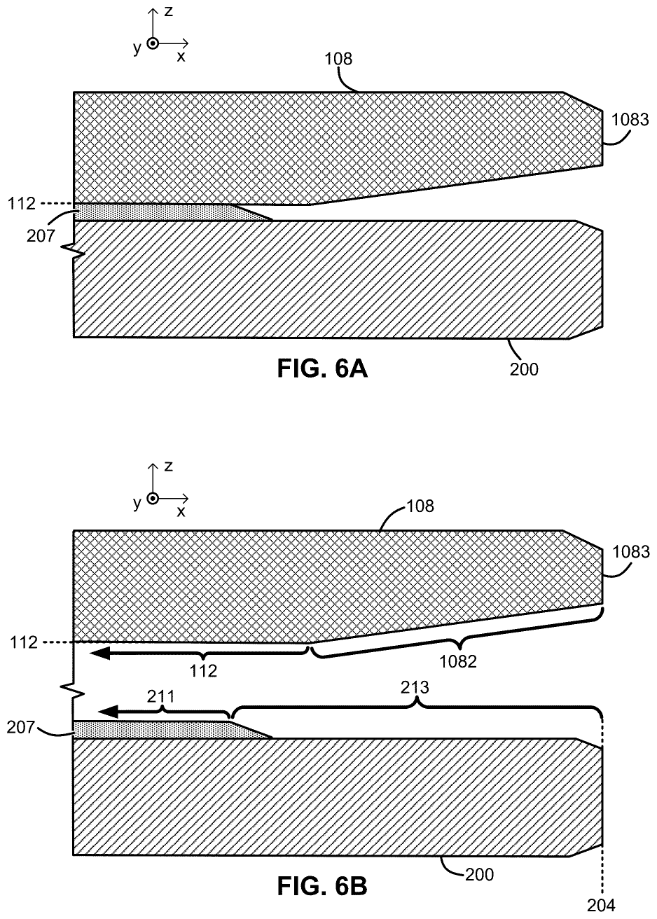

FIG. 5 illustrates a plan view (a view from along the z axis) of an example embodiment of a substrate 200, an applique 106, a feature pattern 201, and a planarization zone 211. Also, the edges 202 of the feature pattern 201 collectively define a border of the feature pattern 201. And FIGS. 6A-B are partial sectional views, taken along the plane that is indicated by the line XX in FIG. 5, that illustrate the substrate 200 and the superstrate 108. FIG. 6A illustrates the superstrate 108 and the substrate 200 when the superstrate 108 is still in contact with the planarized layer 207. FIG. 6B illustrates the superstrate 108 and the substrate 200 after the superstrate 108 is separated from the planarized layer 207.

The substrate-positioning stage 107, which supports the applique 106 and the substrate 200, can move the applique 106 and the substrate 200 along both the x axis and the y axis. This allows the substrate-positioning stage 107 to position each portion of the substrate 200 under the fluid dispenser 122, which deposits drops of formable material 124 on the substrate 200, and then position the substrate 200 under the superstrate 108, which, in this embodiment, planarizes the formable material 124 that was deposited on the substrate 200.

The planarization zone 211 on the substrate 200 is an area where formable material 124 will be planarized, and the boundary of the planarization zone 211 can be controlled by the drop pattern and the process conditions. In this example embodiment, the exemption zone 213 is the portion of the substrate 200 that is between the edge 204 of the substrate 200 and the inner perimeter of etched-in features on the substrate 200.

The superstrate 108 can include a tapered region 1082, as shown in FIGS. 6A-B. The tapered region 1082 may have a beveled profile or a curved profile that has, for example, a specified radius or other specified shape. In some embodiments, the superstrate 108 does not have a tapered region and is instead flat all the way to the superstrate's edge 1083. In embodiments that include the tapered region 1082, the contact surface 112 is the portion of the superstrate 108 that lies within the tapered region 1082. The contact surface 112 can also be inset within the shape of the contact surface 112, which is defined by the tapered region 1082, and may be a polygon, an ellipse, or a circle when viewed along the z axis. The area of the contact surface 112 can define the size of the top layer 207 (patterned or planarized). In some embodiments, the area of the contact surface 112 is larger than the top layer 207 (patterned or planarized).

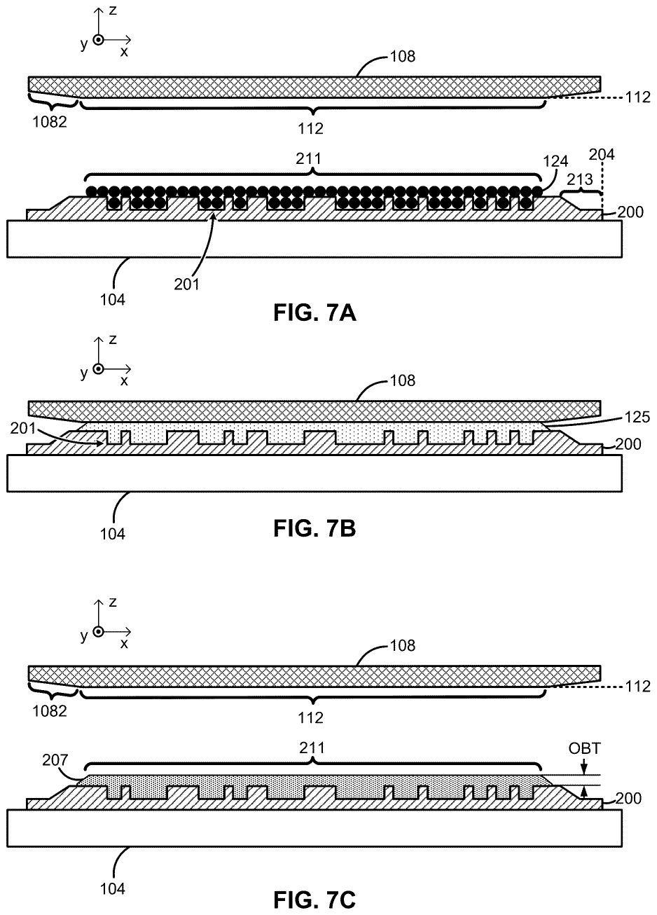

FIGS. 7A-C illustrate a planarization process. As illustrated in FIG. 7A, drops of formable material 124 are dispensed onto the substrate 200 within the planarization zone 211 according to a drop pattern. The drop pattern was generated based on the feature pattern 201, the exemption zone 213, and a specified overburden thickness OBT. The goal of the drop-pattern generation was, for example, to generate a drop pattern that would fill the feature pattern 201 and produce an overburden with the specified overburden thickness OBT across the planarization zone 211. No drops of formable material 124 are deposited in the exemption zone 213.

The feature pattern 201 may be known based on previous processing operations or may be measured using a profilometer, AFM, SEM, or an optical surface profiler based on optical interference effects, such as the Zygo NewView 8200. In the drop pattern, the local volume density of the drops of formable material 124 is varied across the planarization zone 211 depending on the feature pattern 201 (e.g., depending on local variations in the volume requirement of the feature pattern 201). The contact surface 112 of the superstrate 108 is then positioned in contact with the drops of formable material 124.

In FIG. 7B, the contact surface 112 of the superstrate 108 has been brought into full contact with the formable material 124, but a polymerization process has not been started. As the superstrate 108 contacts the formable material 124, the drops of formable material 124 merge and spread to form a formable-material film 125 that fills the field volume (which includes the feature pattern 201) that is between the superstrate 108 and the substrate 200. Preferably, the filling process happens in a uniform manner without any air or gas bubbles being trapped between the superstrate 108 and the substrate 200 in order to minimize non-fill defects. Thus, the field volume may equal the total of (1) the volume requirement of the feature pattern and (2) the volume of the formable material 124 that forms the overburden.

The polymerization process, or curing of the formable material 124, may be initiated with actinic radiation (e.g., UV radiation). For example, the energy source 126 can provide the actinic radiation that causes the formable-material film 125 to cure, solidify, or cross-link, thereby forming a planarized layer 207 on the substrate 200. Additionally, the curing of the formable-material film 125 can also be conducted by using heat, pressure, a chemical reaction, other types of radiation, or any combination of these. Once the planarized layer 207 is formed, the superstrate 108 can be separated therefrom. FIG. 7C illustrates the planarized layer 207 on the substrate 200 after separation of the superstrate 108. The planarized layer 207 has the specified overburden thickness OBT.

The substrate 200 and the planarized layer 207 may then be subjected to additional known steps and processes for device (article) fabrication, including, for example, patterning, curing, oxidation, layer formation, deposition, doping, planarization, etching, formable material removal, dicing, bonding, and packaging, and the like. Thus, a feature pattern may be added on, to, or through the planarized layer 207, and the planarized layer 207 (which has the feature pattern) may be used as the substrate for another planarization process. If the planarized layer 207 (which has the feature pattern) is used as the substrate for another planarization process, the planarization zone 211 may be modified. For example, the exemption zone 213 may extend farther away from the edge 204 of the substrate 200, and the radius of the planarization zone 211 may decrease. Additionally, the substrate 200 may be processed to produce a plurality of articles (e.g., devices).

However, in some circumstances, the shaping system 100 may be instructed to form a top layer 201 with a different desired overburden thickness OBT on the same feature pattern 201 (e.g., on a different substrate 200 that has the same feature pattern 201). The overburden thickness OBT can be controlled by adjusting one or more process parameters, such as the following: drop pattern density, drop volume, superstrate-position trajectory, and superstrate-force trajectory. And the overburden thickness OBT has an impact on the spread velocity via the capillary pressure as the formable material 124 spreads toward the substrate's edge 204, which can impact the quality of the top layer 207.

For example, a control device 130 may control a shaping system 100 to deposit the drops of formable material 124 in FIG. 7A onto a substrate 200 according to first drop pattern, which has a first drop-pattern radius. If the control device 130 receives an instruction to increase the overburden thickness OBT to a second specified overburden thickness (which is less than the first overburden thickness), the control device 130 may generate a new drop pattern that also has the first drop-pattern radius and that deposits a greater volume of formable material 124 (to produce the increased overburden thickness OBT). For example, the new drop pattern may have a greater drop density or larger drop sizes. However, the spread velocity of the formable material 124 toward the substrate's edge 204 changes with the increase to the overburden thickness OBT. Accordingly, to satisfy the constraints imposed by (1) the greater overburden thickness and (2) the goal of a high-quality top layer 207, the applicant has found that the control device 130 can generate a new drop pattern that has a radius that is less than the first drop-pattern radius, which will improve the quality of the top layer 207. Thus, in some circumstances, the drop-pattern radius may decrease as the overburden thickness increases.

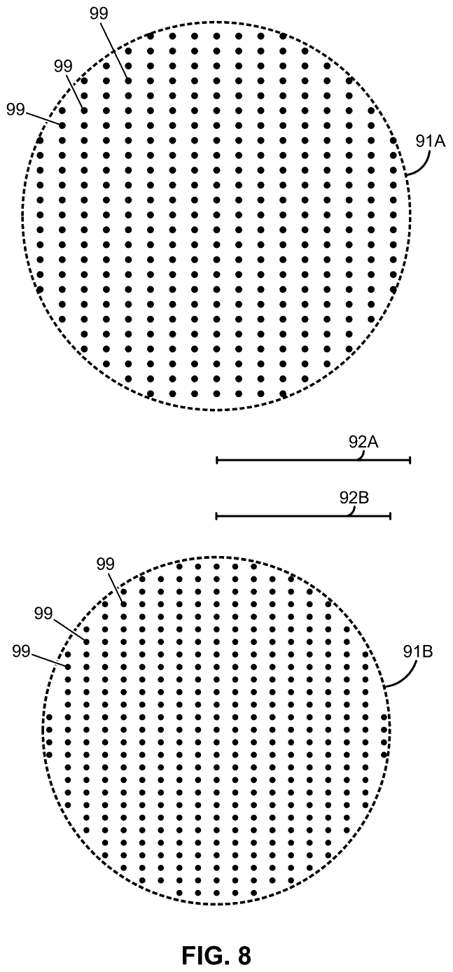

For example, FIG. 8 illustrates example embodiments of a first drop pattern 91A and a second drop pattern 91B. The drop patterns 91 include a respective plurality of drop locations 99. Also, each drop location 99 may have a respective specified drop volume. The drop patterns 91 in FIG. 8 are examples. Some drop patterns include fewer or more drop locations 99 (e.g., millions of drop locations) and include drop locations 99 that are arranged differently. Also, in some embodiments, only the drop locations 99 that have a center that is located within a drop-pattern radius 92 are included in the respective drop pattern 91. Because drops have some width, when a drop is deposited on a substrate 200 according to a drop pattern 91, a part of the drop may be outside of the drop-pattern radius 92 even if the center of the respective drop location 99 is within the drop-pattern radius 92.

The first drop pattern 91A was generated based on a first overburden thickness OBT, and the first drop pattern 91A has a first drop-pattern radius 92A. The second drop pattern 91B was generated for a second overburden thickness OBT that was greater than the first overburden thickness OBT. The feature pattern 201 on the substrate 200 and the exemption zone 213 were unchanged. In some circumstances, the difference in the overburden thickness OBT is the only difference in the characteristics that are used to generate two drop patterns 91. In some circumstances, control parameters of the shaping system 100 can be adjusted when the overburden thickness OBT changes. The second drop pattern 91B includes more drop locations 99 than the first drop pattern 91A, and the second drop-pattern radius 92B is smaller than the first drop-pattern radius 92A. This change in the second drop-pattern radius 92B, relative to the first drop-pattern radius 92A, may reduce or prevent defects (e.g., non-fill defects) near the edge 204 of a substrate 200.

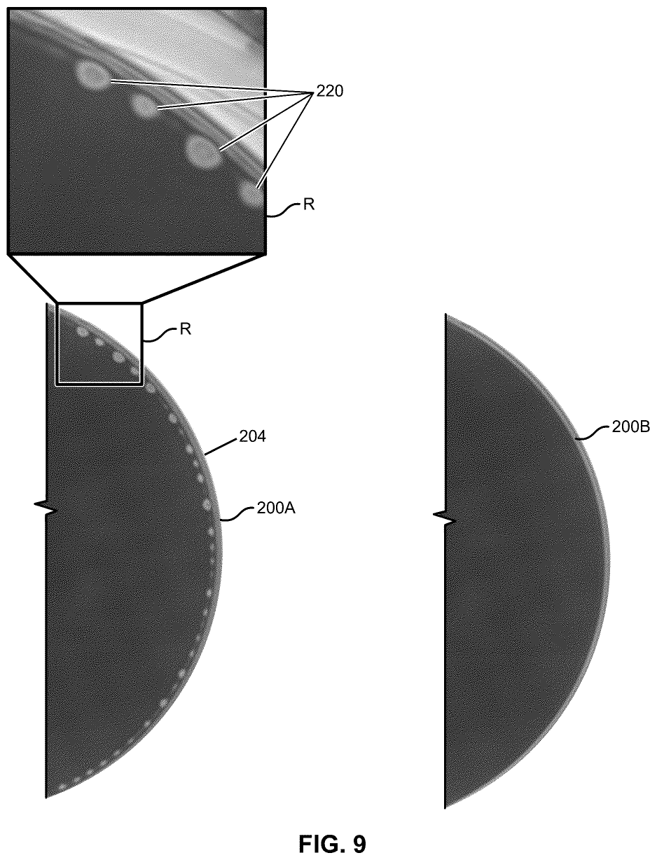

For example, FIG. 9 illustrates example embodiments of images of top layers 207 on substrates 200. Shaping operations were performed on the substrates 200 using identical characteristics (e.g., parameters), and their drop patterns were generated using characteristics that were identical except for their respective drop-pattern radiuses: the drop-pattern radius of the drop pattern that was used to produce the second substrate 200B is smaller than the drop-pattern radius of the drop pattern that was used to produce the first substrate 200A (although the different drop-pattern radiuses were the only difference in the characteristics used to generate the drop patterns, the generated drop patterns may have other differences, including differences in drop locations and their respective drop volumes). The first substrate 200A includes defects 220 near the edge 204. Region R, which includes some of the defects 220, is shown in a magnified view. The second substrate 200B does not include the defects. Accordingly, a properly set drop-pattern radius for a drop pattern may help to prevent the defects 220 that are included in the first substrate 200A.

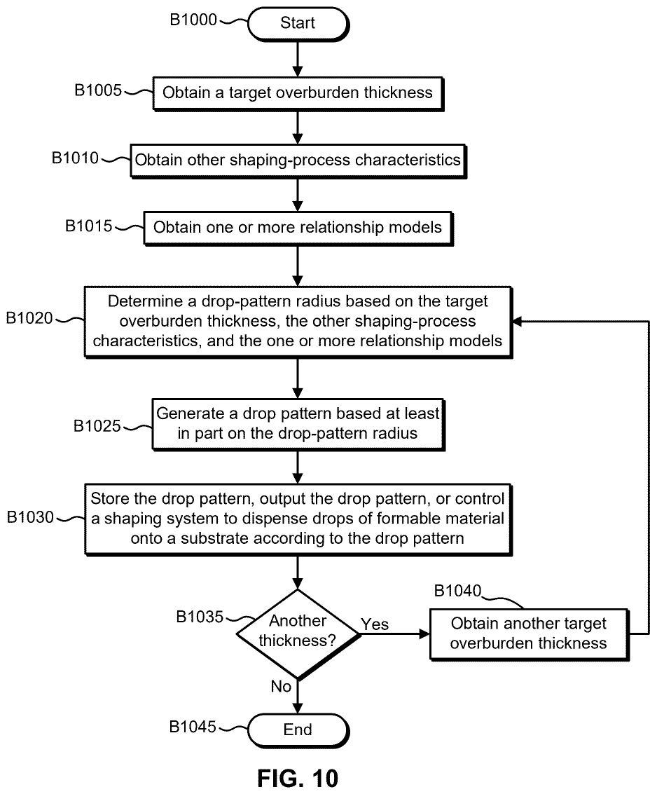

FIG. 10 illustrates an example embodiment of an operational flow for generating a drop pattern. Although this operational flow and the other operational flows that are described herein are each presented in a certain respective order, some embodiments of these operational flows perform at least some of the operations in different orders than the presented orders. Examples of different orders include concurrent, parallel, overlapping, reordered, simultaneous, incremental, and interleaved orders. Also, some embodiments of these operational flows include operations (e.g., blocks) from more than one of the operational flows that are described herein. Thus, some embodiments of the operational flows may omit blocks, add blocks (e.g., include blocks from other operational flows that are described herein), change the order of the blocks, combine blocks, or divide blocks into more blocks relative to the example embodiments of the operational flows that are described herein.

Furthermore, although this operational flow and the other operational flows are performed by a control device 130, some embodiments of these operational flows are performed by two or more control devices 130 or by one or more other specially-configured computing devices (e.g., one or more drop-pattern-generation devices). Additionally, because a control device 130 may constitute a controller, some embodiments of these operational flows are performed by one or more controllers.

In FIG. 10, the flow starts in block B1000 and then moves to block B1005, where a control device 130 obtains (e.g., retrieves from storage, acquires from another device, acquires from user input) a target overburden thickness. The target overburden thickness indicates a goal for an overburden thickness (e.g., a desired overburden thickness).

In block B1010, the control device 130 obtains (e.g., retrieves from storage, acquires from another device, acquires from user input) other shaping-process characteristics (e.g., other shaping-process parameters) for a shaping process. Because an overburden thickness (e.g., a target overburden thickness) is a shaping-process characteristic, this description uses “other shaping-process characteristic” to refer to any shaping-process characteristic that is not an overburden thickness. In some embodiments, the other shaping-process characteristics include one or more of the following: the size of the planarization zone 211, a volume requirement of the substrate 200 (e.g., feature-pattern information (such as dimensions of the features, orientations of the features, locations of the features)), coatings on the substrate 200, a drop volume, formable-material characteristics, coatings on the superstrate 108, and spread time. Also, the feature-pattern information may include a feature-pattern map, which may be represented by an image (e.g., bitmap, PNG) in which the respective value of each tile (e.g., pixel, voxel) indicates a volume (e.g., width, length, and depth)—and thus a volume requirement—of the feature pattern 201 at the tile's respective location or may be generated based on layout data, such as GDSII data or OASIS data.

Furthermore, a material map defines a respective formable-material volume requirement that includes both the volume requirement of the substrate 200 and the overburden volume requirement (the volume of the overburden layer) at different locations across some or all of the substrate 200. For example, a material map may be an image (e.g., bitmap, PNG) in which the respective value of each tile (e.g., pixel, voxel) indicates a volume requirement of formable material 124 (at the tile's respective location) that is the sum of the volume requirement of the substrate 200 at the tile and the volume requirement of the overburden at the tile. And a material map may also be generated based on layout data, such as GDSII data or OASIS data. In some embodiments, a material map is generated based on the volume requirement of the substrate 200 and on the target overburden thickness (e.g., by adding the volume requirement of the substrate 200 at each tile to the respective volume requirement of the overburden at the tile). The actual features on the substrate represented by the feature-pattern information may have lateral dimensions that are very small (on the order of 1-100 nm) while the feature-pattern map may have tiles (1-100 μm) that are much larger than the lateral feature-pattern information.

Then, in block B1015, the control device 130 obtains (e.g., retrieves from storage, acquires from another device, acquires from user input) one or more relationship models, which indicate relationships (e.g., the control relationship (or model parameter space)) between the shaping-process characteristics (which include the overburden thickness and other shaping-process characteristics) and drop-pattern radiuses. For example, a relationship model may be a look-up table (LUT) that maps shaping-process characteristics to drop-pattern radiuses. Some embodiments of LUTs use the shaping-process characteristics as index values and include a respective drop-pattern radius for each range of a plurality of ranges of index values. Also, some embodiments of LUTs are, in effect, fluid-filling models that are based on geometry (e.g., feature-pattern geometry, superstrate geometry) and fluid-spread characteristics. And a relationship model may be another model, such as a trained machine-learning model (e.g., an artificial neural network).

Next, in block B1020, the control device 130 determines a drop-pattern radius based on the target overburden thickness, the other shaping-process characteristics, and the one or more relationship models. For example, in some embodiments in which the one or more relationship models are LUTs, the control device 130 can use the shaping-process characteristics as index values to determine (e.g., look-up) the corresponding drop-pattern radius or to determine a system factor that is based on (and which describes or models) the effects of the other shaping-process characteristics on the spread of the formable material. Furthermore, in some embodiments, the drop-pattern radius can be described by the following:

$$DPR = SR - ( EZ + ( OBT * SF ) ) , \qquad ( 1 )$$

where DPR is the drop-pattern radius, where SR is the radius of the substrate 200, where EZ is the radial distance (radial width) of the exemption zone 213, where OBT is the target overburden thickness, and where SF is a system factor (which also may be included in a LUT). For example, the SR may be 150 mm, the OBT may be between 0.1 nm and 300 nm, and the DPR may be between 140 mm and 149.5 mm. Also for example, a 50 nm change in the OBT may require a change in the DPR of less than a millimeter.

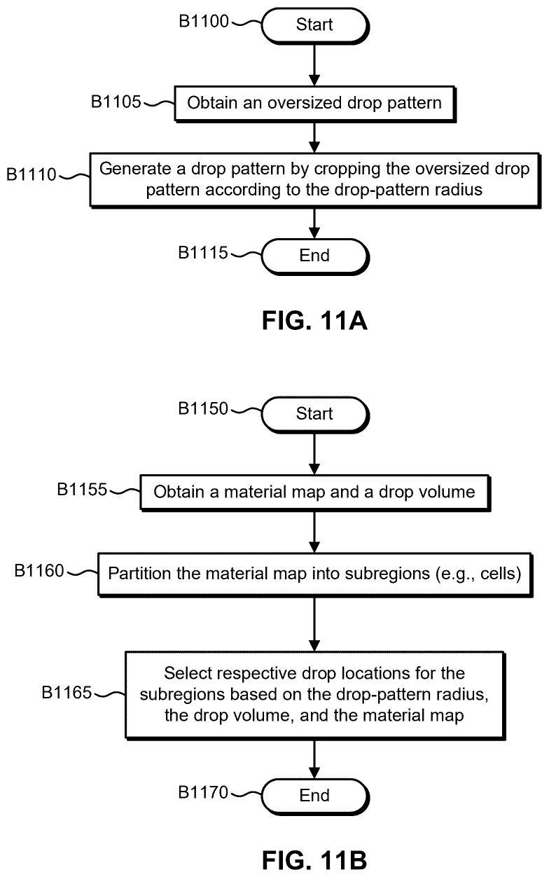

In block B1025, the control device 130 generates a drop pattern based at least in part on the drop-pattern radius, for example as described in FIG. 11A or in FIG. 11B. The drop pattern may also be generated based on at least some of the shaping-process characteristics, and the generated drop pattern may correspond to the overburden thickness and the other shaping-processing characteristics. A drop pattern that corresponds to a specified overburden thickness and other shaping-processing characteristics is a drop pattern that, when used in a shaping process that is performed according to the other shaping-process characteristics, will result in an overburden that has the specified overburden thickness.

Then, in block B1030, the control device 130 stores the drop pattern in one or more computer-readable storage media, outputs the drop pattern to another device (e.g., via a network), or controls a shaping system 100 to dispense drops of formable material 124 onto a substrate 200 according to the drop pattern.

In block B1035, the control device 130 determines whether to perform blocks B1020-B1030 for another target overburden thickness. For example, the control device 130 may determine whether a user has input another target overburden thickness or whether another device has sent another target overburden thickness to the control device 130. If the control device 130 determines to perform blocks B1020-B1030 for another target overburden thickness (B1035=Yes), then the flow moves to block B1040, where the control device 130 obtains another target overburden thickness, and then the flow returns to block B1020. If the control device 130 determines not to perform blocks B1020-B1030 for another target overburden thickness (B1035=No), then the flow ends in block B1045.

FIG. 11A illustrates an example embodiment of an operational flow for generating a drop pattern. For example, the operations in FIG. 11A may be performed in block B1025 in FIG. 10.

The flow starts in block B1100 and then moves to block B1105, where a control device 130 obtains an oversized drop pattern. An oversized drop pattern is oversized relative to a specified planarization zone 211 (i.e., larger than a specified planarization zone 211) or even to a specified substrate 200 (i.e., larger than a specified substrate 200), which allows the oversized drop pattern to be cropped. Also, each oversized drop pattern in a collection of oversized drop patterns may be generated based on a respective specified overburden thickness (e.g., was generated to result in the specified overburden thickness given the other shaping-process characteristics).

The obtained oversized drop pattern may correspond to (e.g., be based on) specified shaping-process characteristics (e.g., the target overburden thickness that was obtained in block B1005, at least some of the shaping-process characteristics that were obtained in block B1010 in FIG. 10). For example, some embodiments of the control device 130 use the target overburden thickness that was obtained in block B1005 and at least some of the shaping-process characteristics that were obtained in block B1010 in FIG. 10 to identify a stored corresponding oversized drop pattern and retrieve the identified corresponding oversized drop pattern. The target overburden thickness (e.g., the target overburden thickness that was obtained in block B1005) may be within a specified range of the specified overburden thickness that was used in the generation of the corresponding oversized drop pattern.

Then, in block B1110, the control device 130 generates a drop pattern by cropping the oversized drop pattern according to the drop-pattern radius. The control device 130 may perform block B1110 when the target overburden thickness (e.g., the target overburden thickness that was obtained in block B1005) is within a specified range of the respective specified overburden thickness that was used in the generation of the oversized drop pattern.

In some embodiments, when cropping the oversized drop pattern according to the drop-pattern radius, the control device 130 removes all drop locations that have a respective drop-location center that is located outside the drop-pattern radius. And in some embodiments, when cropping the oversized drop pattern according to the drop-pattern radius, the control device 130 removes all drop locations for which any part of the respective drop is located outside the drop-pattern radius.

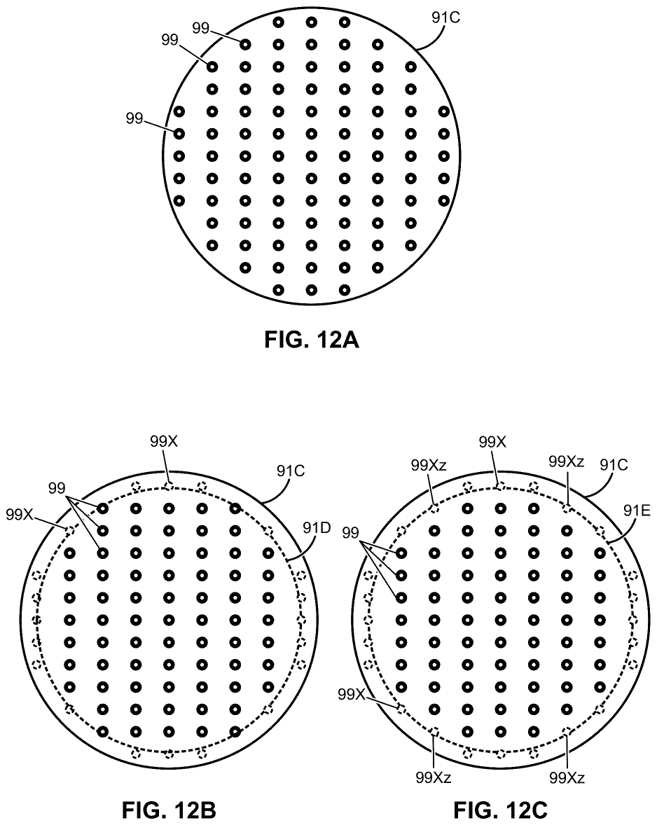

For example, FIG. 12A illustrates an example embodiment of an oversized drop pattern 91C. The oversized drop pattern 91C includes a plurality of drop locations 99. FIG. 12B illustrates an example embodiment of the oversized drop pattern 91C and a first drop pattern 91D that was generated by cropping the oversized drop pattern 91C according to a specified drop-pattern radius. Cropped drop locations 99X, which are drop locations 99 in the oversized drop pattern 91C that are not included in the first drop pattern 91D, are shown in dashed lines in FIG. 12B. The cropping removed, from the oversized drop pattern 91C, all drop locations 99 that have a respective drop-location center that is located outside the specified drop-pattern radius of the first drop pattern 91D.

FIG. 12C illustrates an example embodiment of the oversized drop pattern 91C and a second drop pattern 91E that was generated by cropping the oversized drop pattern 91C according to a specified drop-pattern radius. Cropped drop locations 99X, which are drop locations 99 in the oversized drop pattern 91C that are not included in the second drop pattern 91E, are shown in dashed lines in FIG. 12C. The cropping removed, from the oversized drop pattern 91C, all drop locations 99 for which any part of the respective drop (as indicated by the size of the corresponding circle of the drop location 99) is located outside the specified drop-pattern radius of the second drop pattern 91E. The specified drop-pattern radius of the second drop pattern 91E is identical to the specified drop-pattern radius of the first drop pattern 91D. However, because the cropping removed all drop locations 99 for which any part of the respective drop is located outside the specified drop-pattern radius of the second drop pattern 91E, four drop locations 99Xz that were included in the first drop pattern 91D in FIG. 12B were removed from the second drop pattern 91E.

After block B1110 in FIG. 11A, the flow ends in B1115.

FIG. 11B illustrates an example embodiment of an operational flow for generating a drop pattern. For example, the operations in FIG. 11B may be performed in block B1025 in FIG. 10.

The flow starts in block B1150 and then moves to block B1155, where a control device 130 obtains (e.g., generates) a material map of a substrate and a drop volume (which indicates the volume of a drop of formable material 124). The formable-material volumes of each tile that is indicated by the material map include the volume requirement of the target overburden thickness and the volume requirement of the feature pattern 201 at the tile. For example, the control device 130 may generate a material map based on an obtained feature pattern 201 and on a target overburden thickness (e.g., the formable-material volume of each tile may be the sum of the volume requirement of the target overburden thickness at the tile and of the volume requirement of the feature pattern 201 at the tile).

Next, in block B1160, the control device 130 partitions the material map into subregions (e.g., cells). In some embodiments, all of the subregions have the same size and shape, and, in some embodiments, at least some of the subregions have different sizes or shapes. And, in block B1165, the control device 130 selects respective drop locations for the subregions based on the drop-pattern radius, on the drop volume, and on the material map. The order by which the control device 130 progresses through the subregions may vary. For example, in some embodiments the order is based on one or more of the following: the shapes of the subregions, the spatial relationships of the subregions, the computing environment, and user input. Furthermore, in some embodiments, the respective center of every drop location is located within the drop-pattern radius. And in some embodiments, the entirety of the respective drop (accounting for the drop size) at every drop location is located within the drop-pattern radius.

For example, in block B1165, the control device 130 may generate an initial drop pattern for a selected subregion using a first drop-pattern-generation process and then generate a revised drop pattern for the selected subregion using a second drop-pattern-generation process based on the initial drop pattern. The first drop-pattern-generation process may have a linear runtime and be non-iterative. The second drop-pattern-generation process may use the initial drop pattern as a starting drop pattern and then modify (e.g., revise, refine, optimize) the initial drop pattern, and the second drop-pattern-generation process may be iterative and may have a non-linear runtime.

Also for example, in block B1165, the control device 130 may (a) divide the material map into two rectangular child regions along a division axis, where the formable-material volumes of the two rectangular child regions are approximately equal; (b) determine if the material volume in each rectangular child region is within a range of a specific volume; (c) for each rectangular child region that is not within the range of the specific volume, perform (a) for each rectangular child region as the rectangular region along a division axis that has been rotated by 90 degrees relative to the division axis that was used to generate the rectangular child region; (d) repeat (a)-(c) until all rectangular child regions meet the criteria in (b); and (e) output a drop pattern that includes one or more drop locations inside each rectangular child region that meets the criteria in (b).

Furthermore, for example, in block B1165, the subregions may be cells that are each associated with a respective predetermined fluid volume, each cell may have a hexagonal shape, and the control device 130 may (a) receive a predetermined fluid drop volume and an array of cells corresponding to a desired fill area, wherein each cell in the array is associated with a respective predetermined fluid volume, and wherein each cell has a hexagonal shape; (b) scan the cells according to a scanning sequence for a next unassigned cell and add the next unassigned cell in the scanning sequence to a respective fill set of the next unassigned cell; (c) add unassigned cells neighboring the next unassigned cell to the respective fill set until an aggregate of the respective predetermined fluid volumes of the cells in the respective fill set equals or exceeds the predetermined fluid drop volume; (d) place a fluid drop in the drop pattern within an area associated with the respective fill set and mark all cells in the respective fill set as assigned; and (e) repeat (b)-(d) until all the cells have been assigned and the drop pattern has been generated.

Additionally, for example, in block B1165, the control device 130 may identify uniform-feature segments and a transition region in the material map. Uniform-feature segments are segments of the feature pattern 201 that have uniform features of the same feature density and orientation, and the transition region is an area of the feature pattern 201 between the uniform-feature segments that lacks uniform features and that may contain other non-repeating features. The control device 130 may then select or generate respective drop patterns for the uniform-feature segments (e.g., the selection or generation of a drop pattern may be based on the feature density or the dominant feature orientation of the features in the respective uniform-feature segment), calculate the number of drops that are required to fill the transition region, and generate a respective drop pattern for the transition region. For example, the respective drop pattern for the transition region may minimize a metric that is a weighted sum of inverse distances between drops in the transition region and drops in the uniform-feature segments that are adjacent to the transition region. And the control device 130 may generate a combined drop pattern, which combines the respective drop patterns for the uniform-feature segments and the respective drop pattern for the transition region. After block B1165, the flow ends in block B1170.

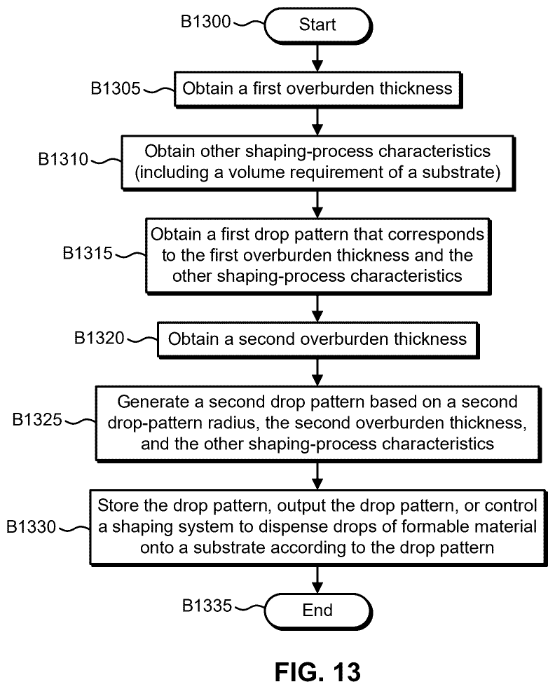

FIG. 13 illustrates an example embodiment of an operational flow for generating a drop pattern. The flow starts in block B1300 and then moves to block B1305, where a control device 130 obtains a first overburden thickness. Next, in block B1310, the control device 130 obtains other shaping-process characteristics, which include a volume requirement of a substrate 200. Then, in block B1315, the control device 130 obtains (e.g., generates, retrieves from memory, receives from another device) a first drop pattern that corresponds to the first overburden thickness and the other shaping-processing characteristics. As noted above, a drop pattern that corresponds to a specified overburden thickness and other shaping-processing characteristics is a drop pattern that, when used in a shaping process that is performed according to the other shaping-process characteristics, will result in an overburden that has the specified overburden thickness. Also, block B1315 may include the operations that are described in FIG. 11A or the operations that are described in FIG. 11B.

Then, in block B1320, the control device 130 obtains a second overburden thickness that is different from the first overburden thickness. And, in block B1325, the control device 130 generates a second drop pattern (that is different from the first drop pattern) based on a second drop-pattern radius (that is different from the first drop-pattern radius), on the second overburden thickness, and on the other shaping-process characteristics. Also, block B1325 may include the operations that are described in FIG. 11A or the operations that are described in FIG. 11B. For example, if the first drop pattern was obtained by cropping an oversized drop pattern according to a first drop-pattern radius, and if the second overburden thickness is sufficiently close to (within a specified range of) the first overburden thickness, then in block B1325 the control device 130 may generate the second drop pattern by cropping the oversized drop pattern according to a second drop-pattern radius. Also for example, if the first drop pattern was obtained by cropping a first oversized drop pattern according to a first drop-pattern radius, and if the second overburden thickness is not sufficiently close to (within a specified range of) the first overburden thickness, then in block B1325 the control device 130 may generate the second drop pattern by cropping a second oversized drop pattern according to a second drop-pattern radius.

In block B1330, the control device 130 stores the second drop pattern in one or more computer-readable storage media, outputs the second drop pattern to another device (e.g., via a network), or controls a shaping system 100 to dispense drops of formable material 124 onto a substrate 200 according to the second drop pattern.

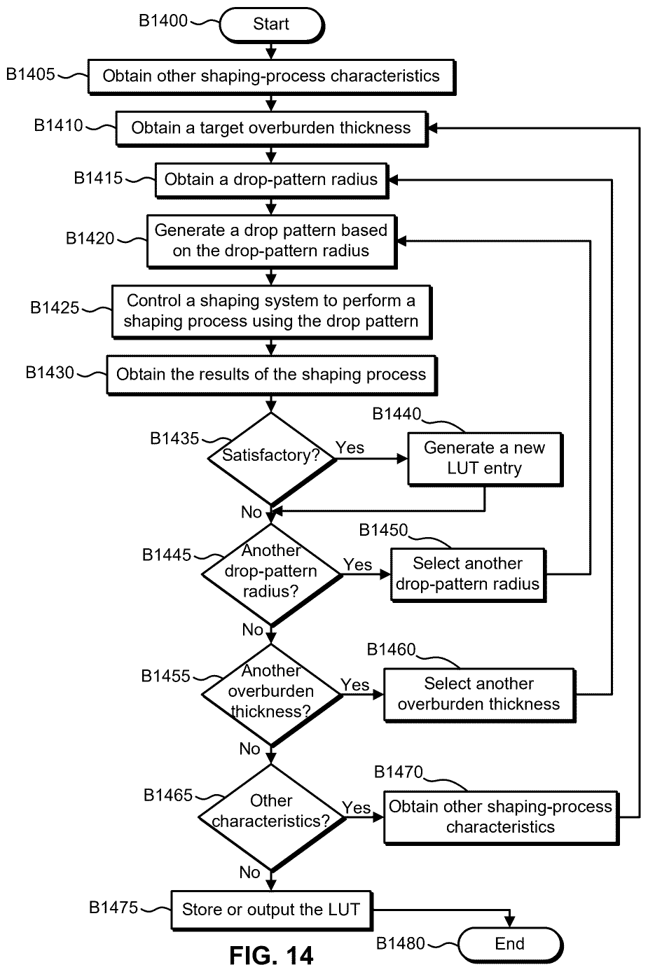

FIG. 14 illustrates an example embodiment of an operational flow for generating a relationship model. In this example embodiment, the relationship model is a lookup table (LUT). The flow begins in block B1400 and moves to block B1405, where a control device 130 obtains other shaping-process characteristics (which are the shaping-process characteristics that are not an overburden thickness). Then, in block B1410, the control device 130 obtains a target overburden thickness. And, in block B1415, the control device 130 obtains (e.g., selects) a drop-pattern radius. For example, the control device 130 may select the next drop-pattern radius in a list (e.g., sequence) of drop-pattern radiuses. Next, in block B1420, the control device 130 generates a drop pattern based on the drop-pattern radius (e.g., as described in FIG. 11A or FIG. 11B) for an unpatterned substrate.

In block B1425, the control device 130 controls a shaping system 100 to perform a shaping process using the drop pattern. During the shaping process, the shaping system 100 deposits drops of formable material 124 onto an unpatterned substrate 200 according to the drop pattern, and the shaping system 100 brings a superstrate 108 into contact with the formable material 124 on the substrate 200 and cures the formable material 124 such that the formable material 124 forms a planarized layer (e.g., a planarized patterned top layer 207) that has the target overburden thickness.

Next, in block B1430, the control device 130 obtains the results of the shaping process. The results indicate whether the planarized layer that was formed in block B1425 satisfies one or more criteria. Examples of criteria includes a maximum number of defects, a maximum size of any defect, a minimum level of overburden uniformity, a planarity, and an absence of formable material in the exemption zone. Obtaining the results may include an inspection (e.g., using an inspection tool or a microscope, a macro visual inspection) by a user who then inputs the results to the control device 130.

Then, in block B1435, the control device 130 determines whether the results are satisfactory. If the results are not satisfactory (B1435=No), then the flow moves to block B1445. If the results are satisfactory (B1435=Yes), then the flow moves to block B1440, where the control device 130 generates a new LUT entry. The new LUT entry includes the target overburden thickness, the other shaping-process characteristics, and the drop-pattern radius. And the LUT maps the target overburden thickness and the other shaping-process characteristics to the drop-pattern radius. The flow then moves to block B1445.

In block B1445, the control device 130 determines whether to perform blocks B1420-B1440 for another drop-pattern radius. For example, the control device 130 may determine whether blocks B1420-B1440 have been performed for every drop-pattern radius in a list of drop-pattern radiuses. If the control device 130 determines to perform blocks B1420-B1440 for another drop-pattern radius (B1445=Yes), then the flow proceeds to block B1450, where the control device 130 selects another drop-pattern radius (which may be different from any other drop-pattern radius that has been used for the current combination of the other shaping-process characteristics and the target overburden thickness). And the flow then moves to block B1420.

If the control device 130 determines not to perform blocks B1420-B1440 for another drop-pattern radius (B1445=No), then the flow proceeds to block B1455.

In block B1450, the control device 130 determines whether to perform blocks B1415-B1450 for another overburden thickness. For example, the control device 130 may determine whether blocks B1415-B1450 have been performed for every overburden thickness in a list of overburden thicknesses. If the control device 130 determines to perform blocks B1415-B1450 for another overburden thickness (B1455=Yes), then the flow moves to block B1460, where the control device 130 selects another target overburden thickness (which may be different from any overburden thickness that has been used for the current other shaping-process characteristics). And the flow then proceeds to block B1415.

If the control device 130 determines not to perform blocks B1415-B1450 for another overburden thickness (B1455=No), then the flow moves to block B1465.

In block B1465, the control device 130 determines whether to perform blocks B1410-B1460 for other shaping-process characteristics. For example, the control device may determine whether blocks B1410-B1460 have been performed for all of the sets (groups) of other shaping-process characteristics in a repository of sets of other shaping-process characteristics. The sets of other shaping-process characteristics may differ from each other and may account for variations in the shaping-process characteristics. If the control device 130 determines to perform blocks B1410-B1460 for other shaping-process characteristics (B1465=Yes), then the flow moves to block B1470, where the control device 130 obtains other shaping-process characteristics (which may have a least once difference compared to any previously obtained other shaping-process characteristics). And the flow then moves to block B1410.

Thus, the control device 130 may generate LUT entries for various combinations of other shaping-process characteristics, overburden thicknesses, and drop-pattern radiuses.

If the control device 130 determines not to perform blocks B1410-B1460 for other shaping-process characteristics (B1465=No), then the flow moves to block B1475. In block B1475, the control device 130 stores or outputs (e.g., sends to another device) the LUT. And the flow ends in block B1480.

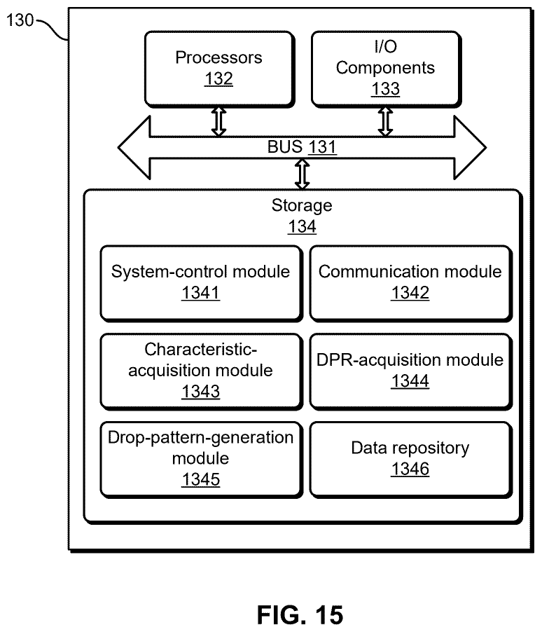

FIG. 15 is a schematic illustration of an example embodiment of a control device 130. The control device 130 includes one or more processors 132, one or more computer-readable storage media 134, one or more I/O components 133, and a bus 131.

The one or more processors 132 are or include one or more central processing units (CPUs), such as microprocessors (e.g., a single core microprocessor, a multi-core microprocessor); one or more graphics processing units (GPUs); one or more application-specific integrated circuits (ASICs); one or more field-programmable-gate arrays (FPGAs); one or more digital signal processors (DSPs); or other electronic circuitry (e.g., other integrated circuits). Furthermore, a processor 132 may be a purpose-built controller or may be a general-purpose controller. The one or more processors 132 may include a plurality of processors that include processors that are both (i) included in the control device 130 and (ii) in communication with the shaping system 100 but not included in the control device 130. And the one or more processors 132 are an example of a processing unit.

The one or more processors 132 may operate based on computer-readable instructions (e.g., in one or more programs) stored on one or more computer-readable storage media 134. As used herein, a computer-readable storage medium 134 includes an article of manufacture, for example a magnetic disk (e.g., a floppy disk, a hard disk), an optical disc (e.g., a CD, a DVD, a Blu-ray), a magneto-optical disk, magnetic tape, and semiconductor memory (e.g., a non-volatile memory card, flash memory, a solid-state drive, SRAM, DRAM, EPROM, EEPROM), and thus a computer-readable storage medium 134 is not a mere transitory, propagating signal. And examples of the one or more computer-readable storage media 134 include networked-attached storage (NAS) devices, intranet-connected storage devices, and internet-connected storage devices. The one or more computer-readable storage media 134, which may include both ROM and RAM, can store computer-readable data or computer-executable instructions. Furthermore, in embodiments where the one or more computer-readable storage media 134 include RAM, the one or more processors 132 can use the RAM as a work area. Additionally, when the control device 130 or the one or more processors 132 are described as obtaining information or data, recording information or data, generating information or data, storing information or data, operating on information or data, processing information or data, etc., the information or data are stored in the one or more computer-readable storage media 134. Also, the one or more computer-readable storage media 134 are an example of a storage unit. And the computer-readable storage media 134 may be distributed among multiple processors 132.

The control device 130 also includes I/O components 133. The I/O components 133 include physical interfaces and communication components (e.g., a GPU, a network-interface controller) that enable communication (wired or wireless) with other members of a shaping system 100 (e.g., a substrate chuck 104, a substrate-positioning stage 107, an imprint head 119, a sensor 141, a fluid dispenser 122, an energy source 126, an imaging device 156, a substrate-heating subsystem 166, back-side strain gauges 143, front-side strain gauges 144, motors or actuators 1091), with other computing devices (e.g., a networked computer), and with input or output devices, which may include a display device, a network device, a keyboard, a mouse, a printing device, a light pen, an optical-storage device, a scanner, a microphone, a drive, a joystick, and a control pad.

Also, the hardware components of the control device 130 communicate via one or more buses 131 or other electrical connections. Examples of buses 131 include a universal serial bus (USB), an IEEE 1394 bus, a PCI bus, an Accelerated Graphics Port (AGP) bus, a Serial AT Attachment (SATA) bus, and a Small Computer System Interface (SCSI) bus.

The control device 130 additionally includes a system-control module 1341, a communication module 1342, a characteristic-acquisition module 1343, a drop-pattern-radius-acquisition (DPR-acquisition) module 1344, and a drop-pattern-generation module 1345. As used herein, a module includes logic, computer-readable data, or computer-executable instructions. In the embodiment shown in FIG. 15, the modules are implemented in software (e.g., Assembly, C, C++, C#, Java, JavaScript, BASIC, Perl, Visual Basic, Python, PHP). However, in some embodiments, the modules are implemented in hardware (e.g., customized circuitry) or, alternatively, a combination of software and hardware. When the modules are implemented, at least in part, in software, then the software can be stored in the one or more computer-readable storage media 134. Also, in some embodiments, the control device 130 includes additional or fewer modules, the modules are combined into fewer modules, or the modules are divided into more modules. And each of these modules may use (e.g., call) other modules. Also, the control device 130 includes a data repository 1346, which stores information, such as shaping-process characteristics, relationship models (e.g., LUTs), and drop patterns.

The system-control module 1341 includes instructions that cause and enable the applicable components (e.g., the one or more processors 132, the storage 134, the I/O components 133) of the control device 130 to communicate with and to control the other members of a shaping system 100 (e.g., to dispense drops of formable material onto a substrate according to a drop pattern or to perform a shaping process). For example, some embodiments of the system-control module 1341 include instructions that cause the applicable components of the control device 130 to control the applicable components of a shaping system 100 to perform at least some of the operations that are described in block 1030 in FIG. 10, in block B1330 in FIG. 13, and in block B1425 in FIG. 14. The applicable components of the control device 130 operating according to the system-control module 1341 realize an example of a system-control unit.

The communication module 1342 includes instructions that cause the applicable components (e.g., the one or more processors 132, the storage 134, the I/O components 133) of the control device 130 to communicate with one or more other computing devices. And the applicable components operating according to the communication module 1342 realize an example of a communication unit.

The characteristic-acquisition module 1343 includes instructions that cause the applicable components (e.g., the one or more processors 132, the storage 134, the I/O components 133) of the control device 130 to control a shaping system 100 to obtain shaping-process characteristics (e.g., overburden thicknesses, other shaping-process characteristics). For example, some embodiments of the characteristic-acquisition module 1343 include instructions that cause the applicable components of the control device 130 to perform at least some of the operations that are described in blocks B1005, B1010, and B1040 in FIG. 10; in blocks B1305, B1310, and B1320 in FIG. 13; and in blocks B1405, B1410, B1460, and B1470 in FIG. 14. The characteristic-acquisition module 1343 may call the system-control module 1341. And the applicable components of the control device 130 operating according to the characteristic-acquisition module 1343 realize an example of a characteristic-acquisition unit.

The DPR-acquisition module 1344 includes instructions that cause the applicable components (e.g., the one or more processors 132, the storage 134, the I/O components 133) of the control device 130 to control a shaping system 100 to obtain (e.g., determine) a drop-pattern radius, for example based on an overburden thickness and other shaping-process characteristics. For example, some embodiments of the DPR-acquisition module 1344 include instructions that cause the applicable components of the control device 130 to perform at least some of the operations that are described in block B1020 in FIG. 10, in blocks B1315 and B1325 in FIG. 13, and in blocks B1415 and B1450 in FIG. 14. The DPR-acquisition module 1344 may call the system-control module 1341. And the applicable components of the control device 130 operating according to the DPR-acquisition module 1344 realize an example of a DPR-acquisition unit.

The drop-pattern-generation module 1345 includes instructions that cause the applicable components (e.g., the one or more processors 132, the storage 134, the I/O components 133) of the control device 130 to control a shaping system 100 to generate a drop pattern based on a drop-pattern radius, to store drop patterns, or to output drop patterns. For example, some embodiments of the drop-pattern-generation module 1345 include instructions that cause the applicable components of the control device 130 to perform at least some of the operations that are described in blocks B1025 and B1030 in FIG. 10; in blocks B1315, B1325, and B1330 in FIG. 13; and in block B1420 in FIG. 14. The drop-pattern-generation module 1345 may call the system-control module 1341. And the applicable components of the control device 130 operating according to the drop-pattern-generation module 1345 realize an example of a drop-pattern-generation unit.

At least some of the above-described devices, systems, and methods can be implemented, at least in part, by providing one or more computer-readable media that contain computer-executable instructions for realizing the above-described operations to one or more computing devices that are configured to read and execute the computer-executable instructions. The systems or devices perform the operations of the above-described embodiments when executing the computer-executable instructions. Also, an operating system on the one or more systems or devices may implement at least some of the operations of the above-described embodiments.

Furthermore, some embodiments use one or more functional units to implement the above-described devices, systems, and methods. The functional units may be implemented in only hardware (e.g., customized circuitry) or in a combination of software and hardware (e.g., a microprocessor that executes software).

In the description, specific details are set forth in order to provide a thorough understanding of the embodiments disclosed. However, well-known methods, procedures, components and circuits may not have been described in detail in order to avoid unnecessarily lengthening the present disclosure.

Also, if a member (e.g., element, part, component) is referred herein as being “on,” “against,” “connected to,” or “coupled to” another member, then the member can be directly on, against, connected or coupled to the other member, but intervening members may also be present between the member and the other member. In contrast, if a member is referred to as being “directly on,” “directly against,” “directly connected to,” or “directly coupled to” another member, then there are no intervening members present between the member and the other member.

Furthermore, the terms “comprising,” “having,” “includes,” “including,” and “containing” are to be construed as open-ended terms unless otherwise noted. Accordingly, these terms, when used in the present specification, specify the presence of described features, integers, steps, operations, elements, materials, or members, but do not preclude the presence or addition of one or more other features, integers, steps, operations, elements, materials, or members that are not explicitly described.

All features disclosed in the specification, including the claims, abstract, and drawings, and all the steps in any method or process disclosed, may be combined in any combination, except combinations where at least some of such features or steps are mutually exclusive.

1. A method comprising:
obtaining a first drop pattern, for a wafer, that forms a first planarized film with a first overburden thickness, wherein the first drop pattern has a first drop-pattern radius;
obtaining a target overburden thickness; and
generating a second drop pattern for the wafer based on a second drop-pattern radius, on the target overburden thickness, and on a volume requirement of the wafer.

2. The method of claim 1, wherein the second drop-pattern radius indicates a maximum distance between a drop location and a center of the second drop pattern.

3. The method of claim 1, further comprising:
determining the second drop-pattern radius based on the target overburden thickness and a look-up table of overburden thicknesses vs drop-pattern radiuses.

4. The method of claim 3, wherein determining the second drop-pattern radius is further based on a dimension of a wafer-edge exemption zone.

5. The method of claim 1,
wherein the second drop-pattern radius is smaller than the first drop-pattern radius, and
wherein generating the second drop pattern includes cropping the first drop pattern.

6. The method of claim 1, wherein the volume requirement of the wafer is a volume of fluid that is required to fill a topography on the wafer.

7. The method of claim 1, further comprising:
depositing drops of formable material on the wafer according to the second drop pattern.

8. The method of claim 7, further comprising:
manufacturing one or more articles, wherein manufacturing the one or more articles includes:
bringing a superstrate into contact with the formable material that has been deposited on the wafer;
after bringing the superstrate into contact with the fluid that has been deposited on the wafer, curing the formable material that has been deposited on the wafer; and
after curing the formable material that has been deposited on the wafer, processing the wafer so as to manufacture the one or more articles.

9. The method of claim 1, wherein the wafer is a patterned wafer or an unpatterned wafer.

10. A system comprising:
at least one processor; and
at least one memory that is in communication with the at least one processor, wherein the at least one memory stores instructions for causing the at least one processor and the at least one memory to:
obtain a first drop pattern, for a wafer, that forms a first planarized film with a first overburden thickness, wherein the first drop pattern has a first drop-pattern radius;
obtain a target overburden thickness; and
generate a second drop pattern for the wafer based on a second drop-pattern radius, on the target overburden thickness, and on a volume requirement of the wafer.

11. The system of claim 10, wherein the second drop-pattern radius indicates a maximum distance between a drop location and a center of the second drop pattern.

12. The system of claim 10, wherein the at least one memory further stores instructions for causing the at least one processor and the at least one memory to:
determine the second drop-pattern radius based on the target overburden thickness and a look-up table of overburden thicknesses vs drop-pattern radiuses.

13. The system of claim 12, wherein the at least one memory further stores instructions for causing the at least one processor and the at least one memory to:
determine the second drop-pattern radius further based on a dimension of a wafer-edge exemption zone.

14. The system of claim 10,
wherein the second drop-pattern radius is smaller than the first drop-pattern radius, and
wherein generating the second drop pattern includes cropping the first drop pattern.

15. The system of claim 10, wherein the volume requirement of the wafer is a volume of fluid that is required to fill a topography on the wafer.

16. The system of claim 10, wherein the at least one memory further stores instructions for causing the at least one processor and the at least one memory to:
control a fluid dispenser to deposit drops of formable material on the wafer according to the second drop pattern.

17. One or more computer-readable storage media storing instructions that, when executed by one or more computing devices, cause the one or more computing devices to perform operations comprising:
obtaining a first drop pattern, for a wafer, that forms a first planarized film with a first overburden thickness, wherein the first drop pattern has a first drop-pattern radius;
obtaining a target overburden thickness; and
generating a second drop pattern for the wafer based on a second drop-pattern radius, on the target overburden thickness, and on a volume requirement of the wafer.

18. The one or more computer-readable storage media of claim 17, wherein the second drop-pattern radius indicates a maximum distance between a drop location and a center of the second drop pattern.

19. The one or more computer-readable storage media of claim 17, wherein the operations further comprise:
controlling a fluid dispenser to deposit drops of formable material on the wafer according to the second drop pattern.

20. The one or more computer-readable storage media of claim 17, wherein the operations further comprise:
determining the second drop-pattern radius based on the target overburden thickness and a look-up table of overburden thicknesses vs drop-pattern radiuses.
